(19) United States
(12) Patent Application Publication
(10) Pub. No.: US 2025/0349813 A1
(43) Pub. Date: Nov. 13, 2025

(54) PACKAGE-ON-PACKAGE WITH DIFFERENT TYPES OF MEMORY

(71) Applicant: QUALCOMM Incorporated, San Diego, CA (US)

(72) Inventors: Piyush GUPTA, San Diego, CA (US); Boris Dimitrov ANDREEV, San Diego, CA (US); Vaishnav SRINIVAS, Oceanside, CA (US); Subbarao PALACHARLA, San Diego, CA (US); Girish BHAT, San Diego, CA (US)

(21) Appl. No.: 19/200,349

(22) Filed: May 6, 2025

Related U.S. Application Data
(60) Provisional application No. 63/644,250, filed on May 8, 2024.

(51) Int. Cl. H01L 25/18; H01L 21/48; H01L 21/56; H01L 23/00; H01L 23/367; H01L 23/498; H01L 23/538; H01L 25/16; H10B 80/00; H10D 80/30

(52) U.S. Cl. CPC H01L 25/18; H01L 23/3677; H01L 23/49838; H01L 23/5385; H10B 80/00; H10D 80/30; H01L 21/4853; H01L 21/4871; H01L 21/56; H01L 24/16; H01L 25/16; H01L 2224/16227; H01L 2224/16237; H01L 2924/1431; H01L 2924/1436

(57) ABSTRACT

Various embodiments may include a Package on Package (PoP) having a bottom package comprising a system-on-chip (SoC) and a bottom substrate, a top package comprising a top substrate, a first memory die, and a second memory die, wherein the first and second memory dies are different in at least one of: memory type, memory density, or memory capacity, an interposer electronically connecting the top package and the bottom package, and a heat sink covering at least a portion of the top package. The SoC may include a non-uniform memory access (NUMA) mechanism configured to manage data interleaving, memory write requests, memory access requests across the first and second memory dies.

### CROSS-REFERENCE TO RELATED APPLICATION

This application claims priority to and the benefit of U.S. Provisional Application Ser. No. 63/644,250, filed in the United States Patent and Trademark Office on May 8, 2024, the entire content of which is incorporated herein by reference as if fully set forth below in its entirety and for all applicable purposes.

Various aspects relate to package-on-package (PoP) integrated circuit assemblies that include two or more different types of dynamic random access memory (DRAM).

### BACKGROUND

A package may include a substrate and integrated devices. These components are coupled together to provide a package that may perform various electrical functions. There is an ongoing need to provide better-performing packages. Moreover, there is also an ongoing need to reduce the overall size of the packages.

### SUMMARY

Various aspects relate to package-on-package (PoP) integrated circuit assemblies that include two or more different types of dynamic random access memory (DRAM).

One example provides a package comprising a first substrate; an integrated device coupled to the first substrate; a second substrate; a heat sink coupled to the second substrate; a first memory device coupled to the second substrate; and a second memory device coupled to the second substrate, wherein the second memory device includes a different type of memory from the first memory device.

One example includes a PoP having a bottom package including a system-on-chip (SoC) and a bottom substrate, and a top package including a top substrate, a first memory die, and a second memory die. The first and second memory dies are of different types, such as a different memory type, memory density, or memory capacity. An interposer layer may electronically connect the top package and the bottom package, and a heat sink covering at least a portion of the top package may be included to conduct heat away from the two memory dies. The SoC may include a non-uniform memory access (NUMA) mechanism configured to manage data interleaving, memory write requests, memory access requests across the first and second memory dies.

### BRIEF DESCRIPTION OF THE DRAWINGS

Various features, nature and advantages may become apparent from the detailed description set forth below when taken in conjunction with the drawings in which like reference characters identify correspondingly throughout.

FIGS. 1-4 illustrate exemplary cross-sectional profile views of a packages according to various embodiments.

FIG. 5 illustrates exemplary plan views of various packages.

FIG. 6 illustrates exemplary temperature maps for various packages.

FIG. 7 illustrates an exemplary cross-sectional profile view of a package that includes substrates, integrated devices and a heat sink.

FIG. 8 illustrates an exemplary plan view of a package.

FIG. 9 illustrates an exemplary temperature map of a package.

FIG. 10 illustrates an exemplary cross-sectional profile view of an integrated device.

FIGS. 11A-11B are diagrams illustrating sequences for fabricating a package.

FIG. 12 is a process flow diagram illustrating a method for fabricating a PoP.

FIGS. 13A-13B illustrate a sequence for fabricating a substrate.

FIG. 14 is a process flow diagram illustrating a method for fabricating a substrate.

FIG. 15 is a cross-sectional profile view of an embodiment PoP.

FIG. 16 is a cross-sectional profile view of an embodiment PoP.

FIG. 17 is a cross-sectional profile view of an embodiment PoP.

FIG. 18 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The disclosure describes a package comprising a first substrate; an integrated device coupled to the first substrate; a second substrate; a heat sink coupled to the second substrate; a first memory device coupled to the second substrate; and a second memory device coupled to the second substrate, wherein the second memory device includes a different type of memory from the first memory device.

Various embodiments include Package on Package (PoP) devices that have a bottom package with a system-on-chip (SoC), a top package with two different types of memory dies, an interposer layer connecting the bottom and top packages, and a heat sink.1 The SoC in the bottom package may include a non-uniform memory access (NUMA) mechanism that can manage data interleaving, memory write requests, and/or memory access requests across the two memory dies, which may differ in memory type, density, capacity, latency, processing-in-memory capabilities, or heat generation. The bottom substrate may be identical for different combinations of the two memory dies, which reduces the design complexity and cost of the PoP device. The heat sink may have an asymmetric shape to accommodate the different heights of the two memory dies, which may vary depending on the memory type and capacity.

Various embodiments provide PoP configurations and technologies that enable mixing of different types of Dynamic Random Access Memory (DRAM) memories within a single PoP, such as in a split-DRAM format. Mixing memory types provides flexibility and customization in memory options for PoP devices. Various embodiments include combining different memory types and/or memory densities within the same package, enabling the tailoring of memory options to meet the specific needs of individual processing modules, such as Neural Processing Unit (NPU), Graphics Processing Unit (GPU), Central Processing Unit (CPU), etc., within the same SoC. For example, various embodiments enable the use of different memory types, capabilities, and memory densities within the same PoP. In addition to enabling dedication of some memory types to specific processing modules (e.g., NPU, GPU, CPU, etc.), various embodiments enable implementing processor-in-memory (PIM) memory modules within the same SoC, such as to support applications where PIM memories are useful, such as artificial intelligence (AI) processing, in a more cost-effective manner without burdening the entire DRAM with PIM processing. The flexibility and customization provided by various embodiments may support the development of affordable electronic devices with increasing processing capabilities.

With the split-DRAM format package on package (PoP) technology of various embodiments, multiple options can be enabled within the same package. For example, it is possible to change the memory type between a first memory and a second memory. This may be particularly useful for taking advantage of advanced memories, such as Low Power Double Data Rate 5 (LPDDR5) synchronous dynamic random-access memory (SDRAM) that is optimized for low power consumption while offering high data transfer rates, LPDDR5X which is an evolution of LPDDR5, and Low Power Double Data Rate 6 (LPDDR6) which provides low-power memory for mobile devices.

In one embodiment, a first memory type may be 2×LPDDR5, 12 Gigabyte (GB) memory, while a second memory type may be 2×LPDDR6, 12 GB memory.

In another embodiment, it is possible to change the memory density between memory-1 and memory-2. For instance, a first memory type may be 2×LPDDR6, 8 GB memory, while a second memory type may be a 2×LPDDR6, 12 GB memory.

In another embodiment, it is possible to change both the memory type and memory density between the first and second types of memory. For example, a first memory type may be 2×LPDDR5, 8 GB memory, while a second memory type may be 2×LPDDR6, 12 GB memory.

These various embodiments enable the tailoring of memory options to meet the specific needs of individual processing modules, such as NPU, GPU, CPU, etc., within the same SoC.

Various embodiments enable multiple options to be implemented within the same SOC and memory PoP. For example, it is possible to allocate each of the different types of DRAM to different processors (e.g., CPU, GPU, NPU, etc.) and/or function or process modules (e.g., modem, inference engine, input/output module, thermal management, power management, etc.) in the same SoC. As a non-limiting example, a memory device 101 (e.g., first memory device) may be dedicated to the NPU/GPU, while a memory device 107 (e.g., second memory device) is dedicated to the CPU and the rest of the SoC functionality. In another non-limiting example, a memory device 101 may be dedicated to the NPU, while a memory device 107 is dedicated to the CPU, GPU, and the rest of the SoC functionality. In some implementations, the term “dedicated” means that a memory from a memory device is to be used for storing data for a particular device.

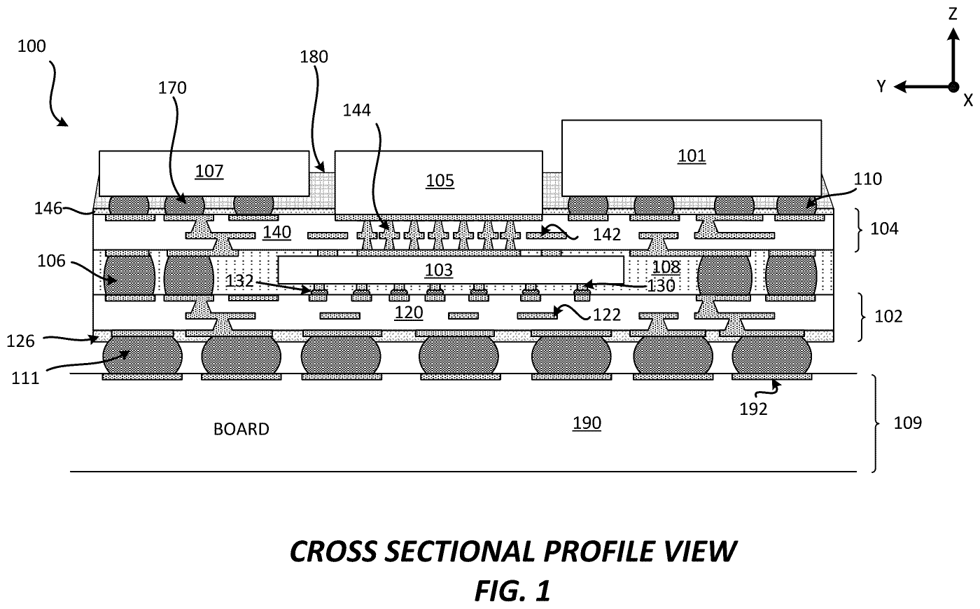

FIG. 1 illustrates a cross-sectional profile view of a package 100 that includes substrates, integrated devices and a heat sink. The package 100 may be implemented as part of a package on package (PoP). The package 100 is coupled to a board 109 through a plurality of solder interconnects 111. The board 109 includes at least one board dielectric layer 190 and a plurality of board interconnects 192. The board 109 may include a printed circuit board (PCB). The package 100 includes a substrate 102, a substrate 104, a memory device 101, an integrated device 103, a memory device 107, a heat sink 105, and an encapsulation layer 108.

In some implementations, the memory device 101 may be a first memory device and the memory device 107 may be a second memory device. In some implementations, the memory device 107 may be a first memory device and the memory device 101 may be a second memory device. The memory device 101 and the memory device 107 may be different types of memories, such as different memory types, memory technology, memory density, memory capacity and/or memory architecture configuration. Thus, the memory device 101 may be a first type of memory device and the memory device 107 may be a second type of memory device. In some implementations, the memory device 101 may be a first memory and the memory device 107 may be a second memory. In one example, the memory device 101 may include a LPDDR5 memory and the memory device 107 may include a LPDDR6 memory. In some implementations, the LPDDR5 memory may include a 16 bit bus, and the LPDDR6 memory may include a 24 bit bus. In some implementations, the LPDDR5 memory may include a 16 bit burst length, and the LPDDR6 memory may include a 24 bit burst length. In some implementations, the LPDDR5 memory may include a same amount of memory capacity (e.g., 12 GB) as the amount of memory capacity (e.g., 12 GB) in the LPDDR6 memory. In some implementations, the LPDDR6 memory may include more memory capacity (e.g., 12 GB) than the amount of memory capacity (e.g., 8 GB) in the LPDDR5 memory. In some implementations, the LPDDR5 memory may include more memory capacity (e.g., 12 GB) than the amount of memory capacity (e.g., 8 GB) in the LPDDR6 memory. The amount of memory (e.g., memory capacity) mentioned above is merely exemplary. Other implementations may have other memory capacity and/or other memory density. In some implementations, the memory device 101 and the memory device 107, each include a LPDDR5 memory, but each have different of memory capacities and/or have different memory densities. In some implementations, the memory device 101 may include a first chiplet and the second type of memory may include a second chiplet. In some implementations, the memory device 101 may include a first memory package and the second type of memory may include a second memory package. The first memory package may include one or more memory dies. The second memory package may include one or more memory dies. LPDDR5 and/or LPDDR6 are examples of different memory architecture configurations. However, other memory architecture configurations may be used, such as Low Power Double Data Rate Accelerator in Memory (LPDDR-AIM). A memory architecture configuration may specify electrical properties, such as supply voltage, bus architecture, clock rate, bandwidth, cycle times, data transfer speed, etc. The use of 16 bit bus and/or the 24 bit bus is merely an example of a number of bits that a bus for a memory device may use. Other memory devices may use a bus with a different number of bits.

A memory device can be a memory die. In some implementations, a memory device may be a package that includes a memory die. In some implementations, a memory device may include several memories dies. Different implementations may use the memory device 101 and/or the memory device 107 differently. In some implementations, the memory device 101 and/or the memory device 107 may be used, dedicated and/or accessible by any of the integrated devices (e.g., 103). In some implementations, some or all of the memory capacity of the memory device 101 may be used by and/or dedicated to only one or more of the integrated devices (e.g., 103). In some implementations, some or all of the memory capacity of the memory device 107 may be used by and/or dedicated to only one or more of the integrated devices (e.g., 103). In one example, the memory device 101 may be dedicated to the NPU functionality of an integrated device and/or the GPU functionality of an integrated device, and the memory device 107 may be dedicated to the CPU functionality and other functionality of an integrated device. In another example, the memory device 101 may be dedicated to the NPU functionality of an integrated device, and the memory device 107 may be dedicated to the CPU functionality of an integrated device, the GPU functionality of an integrated device and other functionality of an integrated device.

The substrate 102 may be a first substrate (e.g., bottom substrate). The substrate 102 includes at least one dielectric layer 120, a plurality of interconnects 122, and a solder resist layer 126. The at least one dielectric layer 120 may include at least one first dielectric layer. The plurality of interconnects 122 may include a first plurality of interconnects. The substrate 102 may include a first surface (e.g., top surface) and a second surface (e.g., bottom surface).

The substrate 104 may be a second substrate (e.g., top substrate). The substrate 104 includes at least one dielectric layer 140, a plurality of interconnects 142, and a solder resist layer 146. The at least one dielectric layer 140 may include at least one second dielectric layer. The plurality of interconnects 142 may include a second plurality of interconnects. The substrate 104 may include a first surface (e.g., top surface) and a second surface (e.g., bottom surface). The substrate 104 may include a plurality of interconnects 144. The plurality of interconnects 144 may be free of electrical connection with the plurality of interconnects 142. The plurality of interconnects 144 may include plate interconnects, via interconnects and/or stacks of via interconnects.

The integrated device 103 may be a first integrated device. The integrated device 103 may be coupled to the substrate 102 through a plurality of pillar interconnects 130 and a plurality of solder interconnects 132. The integrated device 103 may be coupled to the first surface (e.g., top surface) of the substrate 102 through a plurality of pillar interconnects 130 and a plurality of solder interconnects 132. The integrated device 103 may be coupled to the plurality of interconnects 122 through the plurality of pillar interconnects 130 and the plurality of solder interconnects 132. The plurality of solder interconnects 132 may touch interconnects from the plurality of interconnects 122. The integrated device 103 may include a front side and a backside. The integrated device 103 may be a system on chip (SoC) that includes several dies (e.g., integrated circuit dies), such as a CPU die, a GPU die and/or a NPU die.

The substrate 104 is coupled to the substrate 102 through a plurality of solder interconnects 106. The plurality of solder interconnects 106 are located between the substrate 102 and the substrate 104. The plurality of solder interconnects 106 are coupled to the plurality of interconnects 122 and the plurality of interconnects 142. The integrated device 103 may be located between the substrate 102 and the substrate 104.

The encapsulation layer 108 is coupled to the substrate 102 and the substrate 104. The encapsulation layer 108 is located between the substrate 102 and the substrate 104. The encapsulation layer 108 may at least partially encapsulate the integrated device 103 and/or the plurality of solder interconnects 106. The encapsulation layer 108 may touch the substrate 102, the substrate 104, the integrated device 103 and/or the plurality of solder interconnects 106. For example, the encapsulation layer 108 may touch the back side of the integrated device 103 and/or the side surface of the integrated device 103. The encapsulation layer 108 may be located laterally to the integrated device 103 and/or the plurality of solder interconnects 106. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

The heat sink 105 is coupled to the first surface (e.g., top substrate) of the substrate 104. In some implementations, the heat sink 105 may be coupled to the substrate 104 through a thermal interface material (TIM). In some implementations, the heat sink 105 may be coupled to the substrate 104 through a solder interconnect. The heat sink 105 may at least partially vertically overlap with the integrated device 103. The heat sink 105 may at least partially vertically overlap with the plurality of interconnects 144. The plurality of interconnects 144 may at least partially overlap with the integrated device 103. The plurality of interconnects 144 may touch the back side of the integrated device 103. The heat sink 105 may be a component that includes a relatively high thermal conductivity. The heat sink 105 may include a metal, such as copper (Cu). In some implementations, the plurality of interconnects 144 may be coupled to the back side of the integrated device 103 through a thermal interface material (TIM). In some implementations, the plurality of interconnects 144 may be coupled to the back side of the integrated device 103 through a solder interconnect.

In some implementations, at least some of the heat generated by the integrated device 103 may dissipate through the back side of the integrated device 103, through the plurality of interconnects 144 and through the heat sink 105.

The memory device 101 may be coupled to the substrate 104 through a plurality of solder interconnects 110. The memory device 101 may be coupled to the first surface (e.g., top surface) of the substrate 104 through a plurality of solder interconnects 110. The memory device 101 may at least partially vertically overlap with the integrated device 103. For example, the memory device 101 may vertically overlap with at least part of the integrated device 103. A portion of the memory device 101 may vertically overhang the integrated device 103. For example, a part of the memory device 101 may not vertically overlap with the integrated device 103.

The memory device 107 may be coupled to the substrate 104 through a plurality of solder interconnects 170. The memory device 107 may be coupled to the first surface (e.g., top surface) of the substrate 104 through a plurality of solder interconnects 170. The memory device 107 may at least partially vertically overlap with the integrated device 103. For example, the memory device 107 may vertically overlap with at least part of the integrated device 103. A portion of the memory device 107 may vertically overhang the integrated device 103. For example, a part of the memory device 107 may not vertically overlap with the integrated device 103.

The memory device 101 may be located laterally to the heat sink 105 and/or the memory device 107. The memory device 107 may be located laterally to the heat sink 105 and/or the memory device 101.

It is noted that the sizes and/or shapes of the heat sink and/or the memory devices 101, 107 may vary with different implementations. In particular, the memory device 101 may have a height (e.g., Z dimension) that is greater than (as illustrated) or less than that of the memory device 107. Additionally, the number of integrated devices and/or the number of heat sinks may vary with different implementations. Furthermore, the location and/or the position of the integrated devices and/or the heat sink may vary with different implementations. In some implementations, a package may be coupled to the second substrate (e.g., 104). For example, a memory package comprising a substrate and an integrated device (e.g., memory integrated device) may be coupled to the substrate through a plurality of solder interconnects. In some implementations, the memory device 101 and/or the memory device 107 may conceptually represent a package that includes a substrate and an integrated device.

Some embodiments may include a high dielectric constant underfill (e.g., high-K UF) 180 to provide thermal, electrical, and structural support to the upper package, including the two or more memory devices 101, 107 and heat sink 105. The high-K UF 180 may be a polymer matrix that may contain fillers to enhance thermal, insulation, and structural properties. The high-K UF 180 provides structural integrity but also enhances thermal management and electrical performance. The high-K property of the underfill 180 may aid in thermal management and help device insulation, reducing leakage currents and increasing the overall reliability of the device. The high-K UF 180 may help to dissipate heat, such as by conducting heat from the memory devices 101, 107 to the heat sink 105. The high-K UF 180 may also provide structural support for the upper package of memories, particularly when the different types of memories have different heights (e.g., Z dimensions).

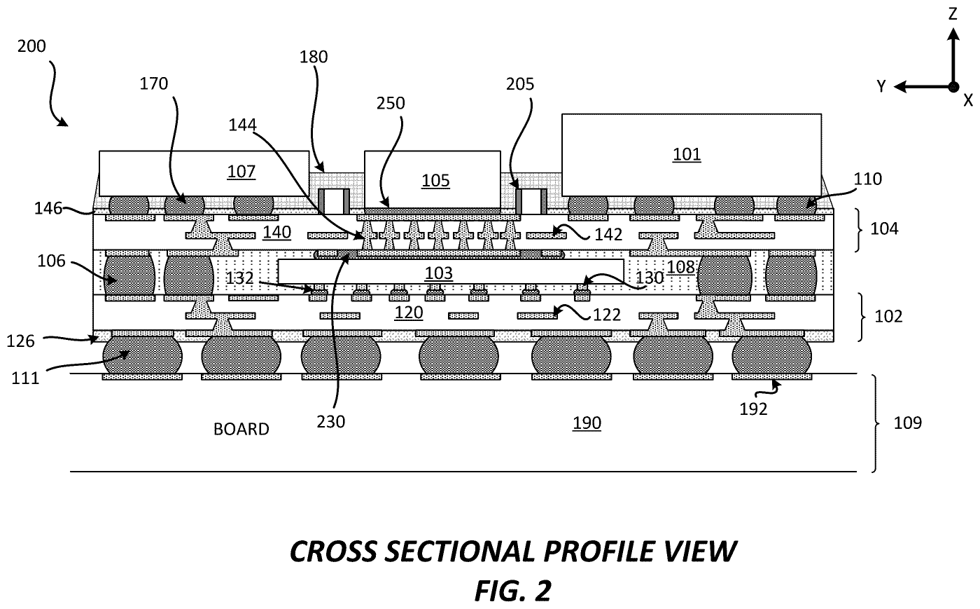

FIG. 2 illustrates a cross-sectional profile view of a package 200 that includes substrates, integrated devices and a heat sink. The package 200 may be implemented as part of a package on package (PoP). The package 200 is coupled to a board 109 through a plurality of solder interconnects 111. The board 109 includes at least one board dielectric layer 190 and a plurality of board interconnects 192. The board 109 may include a printed circuit board (PCB).

The package 200 is similar to the package 100 and may include similar components as the package 100 and may be at least arranged in a similar manner as described for the package 100. The package 200 includes a substrate 102, a substrate 104, a memory device 101, an integrated device 103, a memory device 107, a heat sink 105, a passive device 205 and an encapsulation layer 108. The substrate 102 may be a first substrate (e.g., bottom substrate). The substrate 102 includes at least one dielectric layer 120, a plurality of interconnects 122, and a solder resist layer 126. The at least one dielectric layer 120 may include at least one first dielectric layer. The plurality of interconnects 122 may include a first plurality of interconnects. The substrate 102 may include a first surface (e.g., top surface) and a second surface (e.g., bottom surface).

The substrate 104 may be a second substrate (e.g., top substrate). The substrate 104 includes at least one dielectric layer 140, a plurality of interconnects 142, and a solder resist layer 146. The at least one dielectric layer 140 may include at least one second dielectric layer. The plurality of interconnects 142 may include a second plurality of interconnects. The substrate 104 may include a first surface (e.g., top surface) and a second surface (e.g., bottom surface). The substrate 104 may include a plurality of interconnects 144. The plurality of interconnects 144 may be free of electrical connection with the plurality of interconnects 142. The plurality of interconnects 144 may include plate interconnects, via interconnects and/or stacks of via interconnects.

The integrated device 103 may be a first integrated device. The integrated device 103 may be coupled to the substrate 102 through a plurality of pillar interconnects 130 and a plurality of solder interconnects 132. The integrated device 103 may be coupled to the first surface (e.g., top surface) of the substrate 102 through a plurality of pillar interconnects 130 and a plurality of solder interconnects 132. The integrated device 103 may be coupled to the plurality of interconnects 122 through the plurality of pillar interconnects 130 and the plurality of solder interconnects 132. The plurality of solder interconnects 132 may touch interconnects from the plurality of interconnects 122. The integrated device 103 may include a front side and a backside.

The substrate 104 is coupled to the substrate 102 through a plurality of solder interconnects 106. The plurality of solder interconnects 106 are located between the substrate 102 and the substrate 104. The plurality of solder interconnects 106 are coupled to the plurality of interconnects 122 and the plurality of interconnects 142. The integrated device 103 may be located between the substrate 102 and the substrate 104.

The encapsulation layer 108 is coupled to the substrate 102 and the substrate 104. The encapsulation layer 108 is located between the substrate 102 and the substrate 104. The encapsulation layer 108 may at least partially encapsulate the integrated device 103 and/or the plurality of solder interconnects 106. The encapsulation layer 108 may touch the substrate 102, the substrate 104, the integrated device 103 and/or the plurality of solder interconnects 106. For example, the encapsulation layer 108 may touch the back side of the integrated device 103 and/or the side surface of the integrated device 103. The encapsulation layer 108 may be located laterally to the integrated device 103 and/or the plurality of solder interconnects 106. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

The heat sink 105 is coupled to the first surface (e.g., top substrate) of the substrate 104 through a thermal interface material 250. In some implementations, the heat sink 105 may be coupled to the substrate 104 through a solder interconnect. The heat sink 105 may at least partially vertically overlap with the integrated device 103. The heat sink 105 may at least partially vertically overlap with the plurality of interconnects 144. The plurality of interconnects 144 may at least partially vertically overlap with the integrated device 103. The plurality of interconnects 144 may be coupled to the back side of the integrated device 103 through a thermal interface material 230. In some implementations, the plurality of interconnects 144 may be coupled to the back side of the integrated device 103 through a solder interconnect.

The passive device 205 is coupled to the first surface of the substrate 104. In some implementations, the passive device 205 is coupled to the substrate 104 through a solder interconnect. The passive device 205 may be coupled to an interconnect from the plurality of interconnects 142 of the substrate 104. The passive device 205 may include a capacitor.

In some implementations, at least some of the heat generated by the integrated device 103 may dissipate through the back side of the integrated device 103, through the plurality of interconnects 144 and through the heat sink 105.

The memory device 101 may be coupled to the substrate 104 through a plurality of solder interconnects 110. The memory device 101 may be coupled to the first surface (e.g., top surface) of the substrate 104 through a plurality of solder interconnects 110. The memory device 101 may at least partially vertically overlap with the integrated device 103. For example, the memory device 101 may vertically overlap with at least part of the integrated device 103. A portion of the memory device 101 may vertically overhang the integrated device 103. For example, a part of the memory device 101 may not vertically overlap with the integrated device 103.

The memory device 107 may be coupled to the substrate 104 through a plurality of solder interconnects 170. The memory device 107 may be coupled to the first surface (e.g., top surface) of the substrate 104 through a plurality of solder interconnects 170. The memory device 107 may at least partially vertically overlap with the integrated device 103. For example, the memory device 107 may vertically overlap with at least part of the integrated device 103. A portion of the memory device 107 may vertically overhang the integrated device 103. For example, a part of the memory device 107 may not vertically overlap with the integrated device 103.

The memory device 101 may be located laterally to the heat sink 105 and/or the memory device 107. The memory device 107 may be located laterally to the heat sink 105 and/or the memory device 101.

It is noted that the sizes and/or shapes of the heat sink and/or the memory devices 101, 107 may vary with different implementations. In particular, the memory device 101 may have a height (e.g., Z dimension) that is greater than (as illustrated) or less than that of the memory device 107. Additionally, the number of integrated devices and/or the number of heat sinks may vary with different implementations. Furthermore, the location and/or the position of the integrated devices and/or the heat sink may vary with different implementations. In some implementations, a package may be coupled to the second substrate (e.g., 104). For example, a memory package comprising a substrate and an integrated device (e.g., memory integrated device) may be coupled to the substrate through a plurality of solder interconnects. In some implementations, the memory device 101 and/or the memory device 107 may conceptually represent a package that includes a substrate and an integrated device.

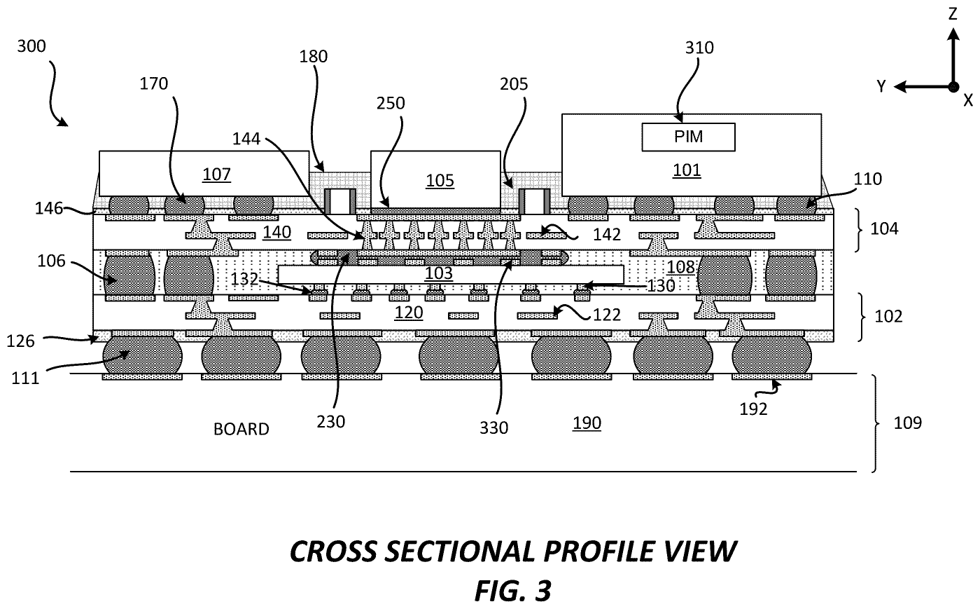

FIG. 3 illustrates a cross-sectional profile view of a package 300 that includes substrates, integrated devices and a heat sink. The package 300 may be implemented as part of a package on package (PoP). The package 300 is coupled to a board 109 through a plurality of solder interconnects 111. The board 109 includes at least one board dielectric layer 190 and a plurality of board interconnects 192. The board 109 may include a printed circuit board (PCB).

In some embodiments, one of the two types of memory may include processor-in-memory (PIM) capabilities. As illustrated in FIG. 3, a memory device 101 may include a PIM processor 310 that is coupled to memory elements and configured with firmware and/or programmable instructions to perform processing operations directly with memory components. This architecture may reduce the latency and energy consumption associated with data movement between the processor and memory in traditional architectures, thereby enhancing performance for certain types of computational tasks. For example, the PIM processor 310 may be programmed and coupled to the memory to support specialized memory operations, such as matrix manipulations and calculations in support of graphical processing or neural network inference processing. Examples of applications in which a PIM-capable memory in the PoP would be beneficial include graphics rendering and simulation, artificial intelligence (AI), machine learning (ML), big data analytics, high-performance computing, and/or cryptography and security. Implementing PIM capabilities in one of the types of memories enables the PoP to support the advantages of PIM memories without burdening the entire DRAM with PIM operations. Thus, the PIM-capable memory may be dedicated to supporting operations or processing modules, such as a GPU and/or NPU, while the other type of memory in the PoP may be dedicated to supporting the CPU and other functionality of the SoC.

As PIM-capable memories may be dedicated to a particular functionality that operates separately from other functions of the SoC within a PoP, memory management functions may need to use NUMA memory access and management technologies. For example, NUMA technologies and software may support dedicating a PIM-capable memory to a particular processor (e.g., a GPU or NPU) and avoiding extending data interleaving across or encompass the PIM-capable memory as the storage, latency, volume, and refresh dynamics may be incompatible with memory usage of other processors.

The package 300 is similar to the package 200 and may include components similar to the package 100 and/or the package 200, and may be at least arranged in a similar manner as described for the package 100 and/or the package 200. The package 300 includes a substrate 102, a substrate 104, a memory device 101, an integrated device 103, a memory device 107, a heat sink 105, a passive device 205 and an encapsulation layer 108. The integrated device 103 includes a plurality of metallization interconnects 330. The plurality of metallization interconnects 330 may include pad interconnects. The plurality of metallization interconnects 330 may be coupled to the back side of the integrated device 103. The plurality of metallization interconnects 330 may be backside metallization interconnects.

The substrate 104 may be coupled to the integrated device 103 through a thermal interface material 230. The plurality of interconnects 144 of the substrate 104 are coupled to the plurality of metallization interconnects 330 of the integrated device 103 through a thermal interface material 230. In some implementations, the plurality of interconnects 144 of the substrate 104 are coupled to the plurality of metallization interconnects 330 of the integrated device 103 through a solder interconnect.

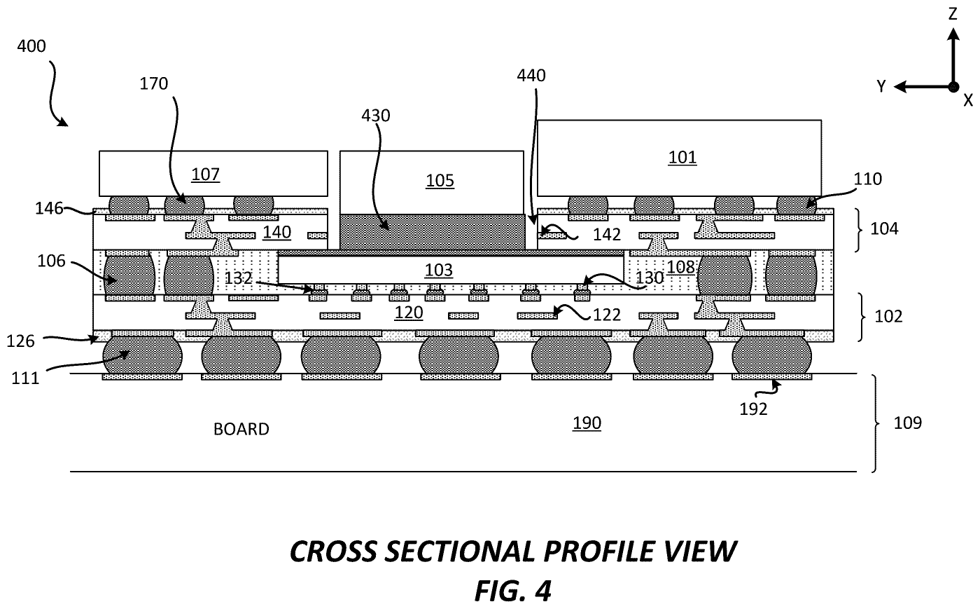

FIG. 4 illustrates a cross-sectional profile view of a package 400 that includes substrates, integrated devices and a heat sink. The package 400 may be implemented as part of a package on package (PoP). The package 400 is coupled to a board 109 through a plurality of solder interconnects 111. The board 109 includes at least one board dielectric layer 190 and a plurality of board interconnects 192. The board 109 may include a printed circuit board (PCB).

The package 400 is similar to the package 100 and may include similar components as the package 100 and may be at least arranged in a similar manner as described for the package 100. The package 400 includes a substrate 102, a substrate 104, a memory device 101, an integrated device 103, a memory device 107, a heat sink 105, a passive device 205 and an encapsulation layer 108.

The substrate 102 may be a first substrate (e.g., bottom substrate). The substrate 102 includes at least one dielectric layer 120, a plurality of interconnects 122, and a solder resist layer 126. The at least one dielectric layer 120 may include at least one first dielectric layer. The plurality of interconnects 122 may include a first plurality of interconnects. The substrate 102 may include a first surface (e.g., top surface) and a second surface (e.g., bottom surface).

The substrate 104 may be a second substrate (e.g., top substrate). The substrate 104 includes at least one dielectric layer 140, a plurality of interconnects 142, and a solder resist layer 146. The at least one dielectric layer 140 may include at least one second dielectric layer. The plurality of interconnects 142 may include a second plurality of interconnects. The substrate 104 may include a first surface (e.g., top surface) and a second surface (e.g., bottom surface). The substrate 104 may include at least one cavity 440. The at least one cavity 440 may extend through the thickness of the substrate 104.

The heat sink 105 is coupled to the integrated device 103 through a thermal interface material 430. The thermal interface material 430 may be located at least partially in the at least one cavity 440 of the substrate 104. The thermal interface material 430 may be coupled to and touch the heat sink 105, the substrate 104 and/or the back side of the integrated device 103. The heat sink 105 may at least partially vertically overlap with the integrated device 103. In some implementations, the integrated device 103 may include a plurality of metallization interconnects 330, as described in the package 300. The thermal interface material 430 may be coupled to and touch the plurality of metallization interconnects 330 of the integrated device 103. Instead of the thermal interface material 430, in some implementations, the heat sink 105 may be coupled to the substrate 104 and/or the integrated device 103 through a solder interconnect.

The encapsulation layer 108 is coupled to the substrate 102 and the substrate 104. The encapsulation layer 108 is located between the substrate 102 and the substrate 104. The encapsulation layer 108 may at least partially encapsulate the integrated device 103 and/or the plurality of solder interconnects 106. The encapsulation layer 108 may touch the substrate 102, the substrate 104, the integrated device 103 and/or the plurality of solder interconnects 106. For example, the encapsulation layer 108 may touch the back side of the integrated device 103 and/or the side surface of the integrated device 103. The encapsulation layer 108 may be located laterally to the integrated device 103 and/or the plurality of solder interconnects 106. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

In some implementations, at least some of the heat generated by the integrated device 103 may dissipate through the back side of the integrated device 103, through the thermal interface material 430, and through the heat sink 105. In some implementations, heat generated by the integrated device 103 may also dissipate through the plurality of interconnects 142 of the substrate 104.

The memory device 101 may be coupled to the substrate 104 through a plurality of solder interconnects 110. The memory device 101 may be coupled to the first surface (e.g., top surface) of the substrate 104 through a plurality of solder interconnects 110. The memory device 101 may at least partially vertically overlap with the integrated device 103.

The memory device 107 may be coupled to the substrate 104 through a plurality of solder interconnects 170. The memory device 107 may be coupled to the first surface (e.g., top surface) of the substrate 104 through a plurality of solder interconnects 170. The memory device 107 may at least partially vertically overlap with the integrated device 103.

The memory device 101 may be located laterally to the heat sink 105 and/or the memory device 107. The memory device 107 may be located laterally to the heat sink 105 and/or the memory device 101.

It is noted that the sizes and/or shapes of the heat sink and/or the two types of memory devices 101, 107 may vary with different implementations. In particular, the memory device 101 may have a height (e.g., Z dimension) that is greater than (as illustrated) or less than that of the memory device 107. Additionally, the number of integrated devices and/or the number of heat sinks may vary with different implementations. Furthermore, the location and/or the position of the integrated devices and/or the heat sink may vary with different implementations. In some implementations, a package may be coupled to the second substrate (e.g., 104). For example, a memory package comprising a substrate and an integrated device (e.g., memory integrated device) may be coupled to the substrate through a plurality of solder interconnects. In some implementations, the memory device 101 and/or the memory device 107 may conceptually represent a package that includes a substrate and an integrated device.

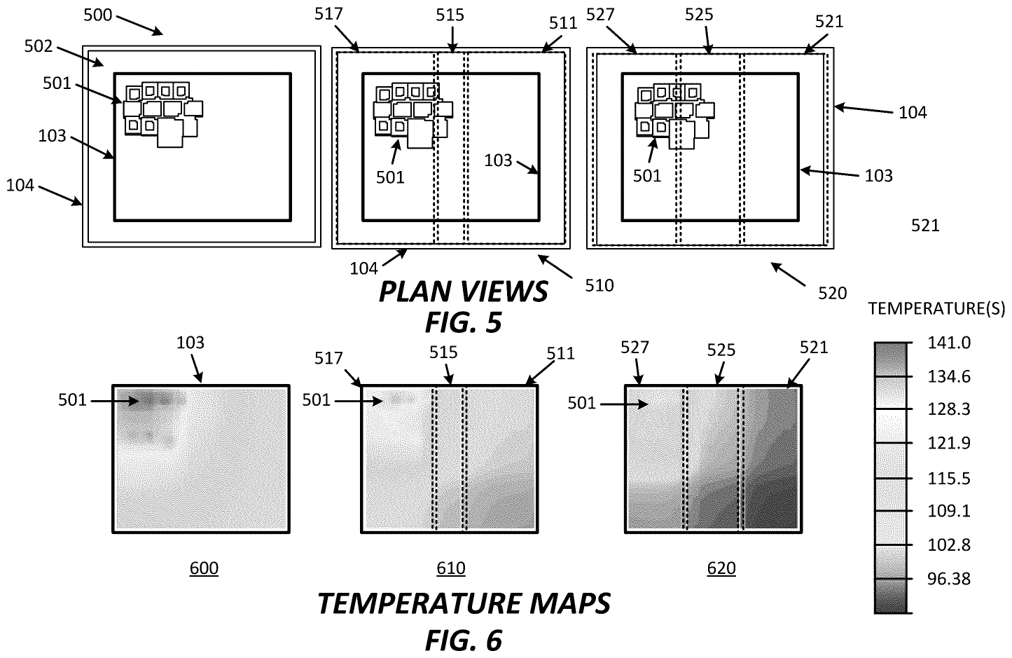

FIG. 5 illustrates plan views of various configurations of a package. FIG. 5 illustrates plan views of a package 500, a package 510 and a package 520. The package 500 includes an integrated device 103, a substrate 104 and an integrated device 502. The package 510 includes the integrated device 103, the substrate 104, an integrated device 511, an integrated device 517 and a heat sink 515. The package 520 includes the integrated device 103, the substrate 104, an integrated device 521, an integrated device 527 and a heat sink 525.

As shown in FIG. 5, the package 500 includes the integrated device 103, the substrate 104 and the integrated device 502. The integrated device 103 includes an active region 501. The active region 501 includes a plurality of transistors. The active region 501 is located in a top left portion of the integrated device 103. The active region 501 of the integrated device 103 will generate a lot of heat in the integrated device 103. The substrate 104 is located between the integrated device 103 and the integrated device 502. The package 500 does not include a heat sink. The integrated device 502 vertically overlaps with the integrated device 103.

As shown in FIG. 5, the package 510 includes the integrated device 103, the substrate 104, the integrated device 511, the integrated device 517 and the heat sink 515. The package 510 may represent the package 100. The heat sink 515 may represent the heat sink 105. The integrated device 511 may represent the memory device 101. The integrated device 517 may represent the memory device 107. The integrated device 103 includes an active region 501. The active region 501 includes a plurality of transistors. The active region 501 is located in a top left portion of the integrated device 103. The substrate 104 is located between the integrated device 103 and the integrated device 511. The substrate 104 is located between the integrated device 103 and the integrated device 517. The substrate 104 is located between the integrated device 103 and the heat sink 515. The integrated device 511 vertically overlaps with at least a portion of the integrated device 103. The integrated device 517 vertically overlaps with at least a portion of the integrated device 103. The heat sink 515 vertically overlaps with at least a portion of the integrated device 103. The heat sink 515 is located laterally to the integrated device 511 and/or the integrated device 517.

As shown in FIG. 5, the package 520 includes the integrated device 103, the substrate 104, the integrated device 521, the integrated device 527 and the heat sink 525. The package 520 may represent the package 100. The heat sink 525 may represent the heat sink 105. The integrated device 521 may represent the memory device 101. The integrated device 527 may represent the memory device 107. The integrated device 103 includes an active region 501. The active region 501 includes a plurality of transistors. The active region 501 is located in a top left portion of the integrated device 103. The substrate 104 is located between the integrated device 103 and the integrated device 521. The substrate 104 is located between the integrated device 103 and the integrated device 527. The substrate 104 is located between the integrated device 103 and the heat sink 525. The integrated device 521 vertically overlaps with at least a portion of the integrated device 103. The integrated device 527 vertically overlaps with at least a portion of the integrated device 103. The heat sink 525 vertically overlaps with at least a portion of the integrated device 103. The heat sink 525 is located laterally to the integrated device 521 and/or the integrated device 527. The heat sink 525 may be larger than the heat sink 515.

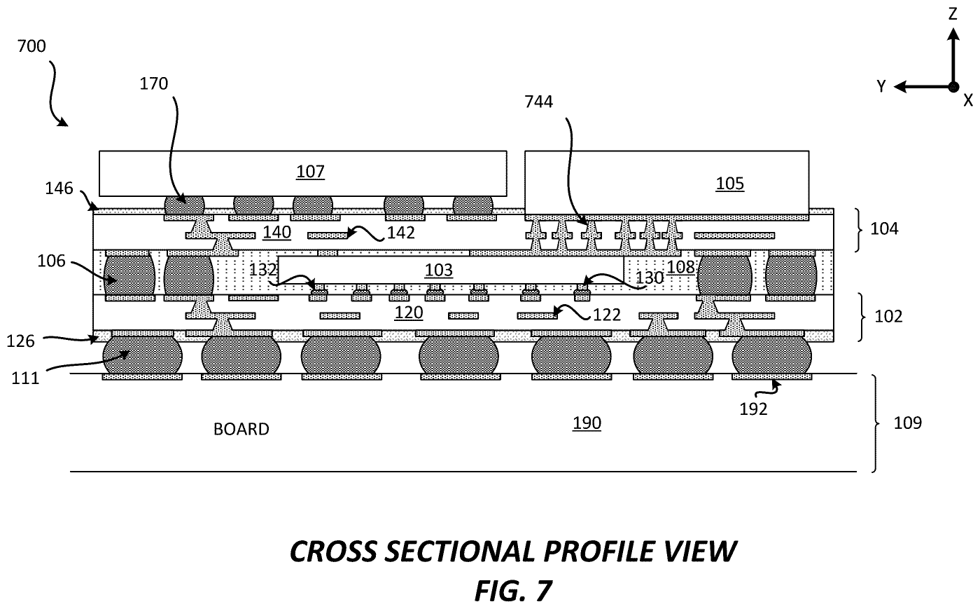

FIG. 6 illustrates exemplary temperature maps for the packages of FIG. 5. FIG. 6 illustrates a temperature map 600 that may correspond to the package 500. FIG. 6 also illustrates a temperature map 610 that may correspond to the package 510. FIG. 6 further illustrates a temperature map 620 that may correspond to the package 520.

The temperature map 600 may illustrate an example of a temperature distribution of the integrated device 103 when no heat sink is present. As shown in FIG. 6, the portion of the integrated device 103 that is above the active region 501 has the highest temperatures and the temperature of a specific portion of the integrated device 103 decreases the further away it is from the active region 501.

The temperature map 610 may illustrate an example of a temperature distribution of the integrated device 103 when a heat sink 515 is present. As shown in FIG. 6, the portion of the integrated device 103 that is above the active region 501 has the highest temperatures and the temperature of a specific portion of the integrated device 103 decreases the further away it is from the active region 501. However, the presence of the heat sink 515 helps reduce the overall temperature of the integrated device 103 and reduce the temperature of the integrated device 103 at certain hot spots, such as the region above the active region 501.

The temperature map 620 may illustrate an example of a temperature distribution of the integrated device 103 when a heat sink 525 is present. The heat sink 525 is bigger than the heat sink 515, which means that more heat can be efficiently dissipated. As shown in FIG. 6, the portion of the integrated device 103 that is above the active region 501 has the highest temperatures and the temperature of a specific portion of the integrated device 103 decreases the further away it is from the active region 501. However, the presence of the heat sink 525, which is larger than the heat sink 515, helps reduce even more (compared to the heat sink 515) the overall temperature of the integrated device 103 and reduce the temperature of the integrated device 103 at certain hot spots, such as the region above the active region 501.

As shown in FIG. 6, the various configurations of the packages help reduce the overall temperatures of integrated devices, as well as reduce local hot spots of integrated devices, which helps improve the performance of the integrated device and/or the performance of the package. The size, shape, location, position of the heat sink can be configured to optimize the heat distribution and/or heat dissipation of the integrated device to provide optimal performance for the integrated device and/or the package. Moreover, the package has compact and/or improved form factors, while still providing improved performance.

Exemplary Package Comprising a Substrate with a Portion Configured as a Heat Sink

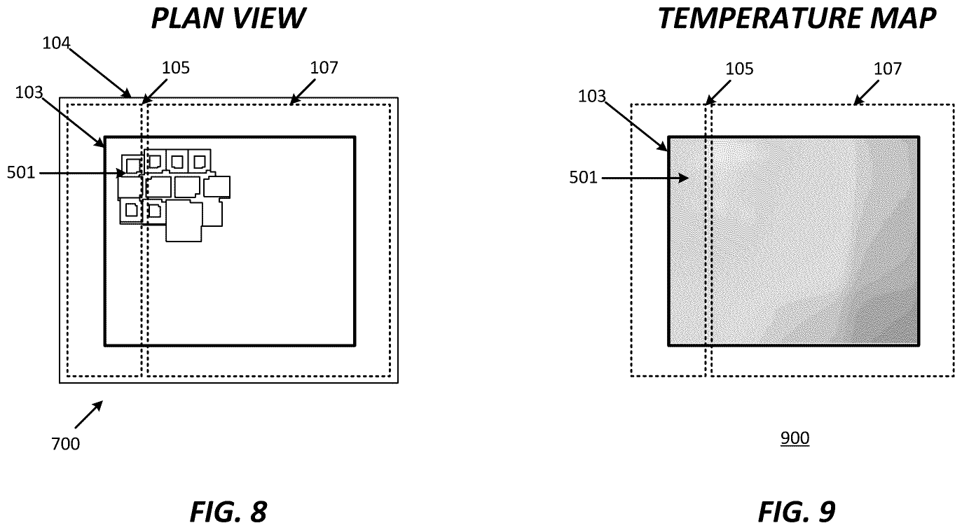

FIG. 7 illustrates a cross-sectional profile view of a package 700 that includes substrates, integrated devices, where a portion of the substrate may be configured as a heat sink. The package 700 may be implemented as part of a package on package (PoP). The package 700 is coupled to a board 109 through a plurality of solder interconnects 111. The board 109 includes at least one board dielectric layer 190 and a plurality of board interconnects 192. The board 109 may include a printed circuit board (PCB).

The package 700 includes a substrate 102, a substrate 104, an integrated device 103, a memory device 107, a heat sink 105 and an encapsulation layer 108. The substrate 102 may be a first substrate (e.g., bottom substrate). The substrate 102 includes at least one dielectric layer 120, a plurality of interconnects 122, and a solder resist layer 126. The at least one dielectric layer 120 may include at least one first dielectric layer. The plurality of interconnects 122 may include a first plurality of interconnects. The substrate 102 may include a first surface (e.g., top surface) and a second surface (e.g., bottom surface).

The substrate 104 may be a second substrate (e.g., top substrate). The substrate 104 includes at least one dielectric layer 140, a plurality of interconnects 142, and a solder resist layer 146. The at least one dielectric layer 140 may include at least one second dielectric layer. The substrate 104 may include a first surface (e.g., top surface) and a second surface (e.g., bottom surface). The substrate 104 may also include a plurality of heat sink interconnects 744. The plurality of heat sink interconnects 744 may be considered part of the plurality of interconnects 142. The plurality of heat sink interconnects 744 may be free of electrical connection with the plurality of interconnects 142. The plurality of heat sink interconnects 744 may include plate interconnects, via interconnects and/or stacks of via interconnects. The plurality of heat sink interconnects 744 may be configured to operate as a heat sink.

The integrated device 103 may be a first integrated device. The integrated device 103 may be coupled to the substrate 102 through a plurality of pillar interconnects 130 and a plurality of solder interconnects 132. The integrated device 103 may be coupled to the first surface (e.g., top surface) of the substrate 102 through a plurality of pillar interconnects 130 and a plurality of solder interconnects 132. The integrated device 103 may be coupled to the plurality of interconnects 122 through the plurality of pillar interconnects 130 and the plurality of solder interconnects 132. The plurality of solder interconnects 132 are touching interconnects from the plurality of interconnects 122. The integrated device 103 may include a front side and a backside.

In some implementations, the back side of the integrated device 103 may touch the substrate 104. For example, the back side of the integrated device 103 may be coupled to and touch the plurality of heat sink interconnects 744. In some implementations, the back side of the integrated device 103 may be coupled to the plurality of heat sink interconnects 744 through a thermal interface material (TIM), an adhesive and/or a solder interconnect.

The substrate 104 is coupled to the substrate 102 through a plurality of solder interconnects 106. The plurality of solder interconnects 106 are located between the substrate 102 and the substrate 104. The plurality of solder interconnects 106 are coupled to the plurality of interconnects 122 and the plurality of interconnects 142.

The encapsulation layer 108 is coupled to the substrate 102 and the substrate 104. The encapsulation layer 108 is located between the substrate 102 and the substrate 104. The encapsulation layer 108 may at least partially encapsulate the integrated device 103 and/or the plurality of solder interconnects 106. The encapsulation layer 108 may touch the substrate 102, the substrate 104, the integrated device 103 and/or the plurality of solder interconnects 106. For example, the encapsulation layer 108 may touch the back side of the integrated device 103 and/or the side surface of the integrated device 103. The encapsulation layer 108 may be located laterally to the integrated device 103 and/or the plurality of solder interconnects 106. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

The heat sink 105 is coupled to the first surface (e.g., top substrate) of the substrate 104. In some implementations, the heat sink 105 may be coupled to the substrate 104 through a thermal interface material (TIM). In some implementations, the heat sink 105 may be coupled to the substrate 104 through a solder interconnect. The heat sink 105 may at least partially vertically overlap with the integrated device 103. The heat sink 105 may at least partially vertically overlap with the plurality of heat sink interconnects 744. The plurality of heat sink interconnects 744 may at least partially vertically overlap with the integrated device 103. The plurality of heat sink interconnects 744 may touch the back side of the integrated device 103. The heat sink 105 may be a component that includes a relatively high thermal conductivity. The heat sink 105 may include a metal.

In some implementations, at least some of the heat generated by the integrated device 103 may dissipate through the back side of the integrated device 103, through the plurality of heat sink interconnects 744 and through the heat sink 105.

The memory device 101 may be coupled to the substrate 104 through a plurality of solder interconnects 170. The memory device 107 may be coupled to the first surface (e.g., top surface) of the substrate 104 through a plurality of solder interconnects 170. The memory device 107 may at least partially vertically overlap with the integrated device 103.

It is noted that the sizes and/or shapes of the heat sink and/or the memory devices 101, 107 may vary with different implementations. In particular, the memory device 101 may have a height (e.g., Z dimension) that is greater than (as illustrated) or less than that of the memory device 107. Additionally, the number of integrated devices and/or the number of heat sinks may vary with different implementations. Furthermore, the location and/or the position of the integrated devices and/or the heat sink may vary with different implementations. In some implementations, a package may be coupled to the second substrate (e.g., 104). For example, a memory package comprising a substrate and an integrated device (e.g., memory integrated device) may be coupled to the substrate through a plurality of solder interconnects. In some implementations, the memory device 107 may conceptually represent a package that includes a substrate and an integrated device.

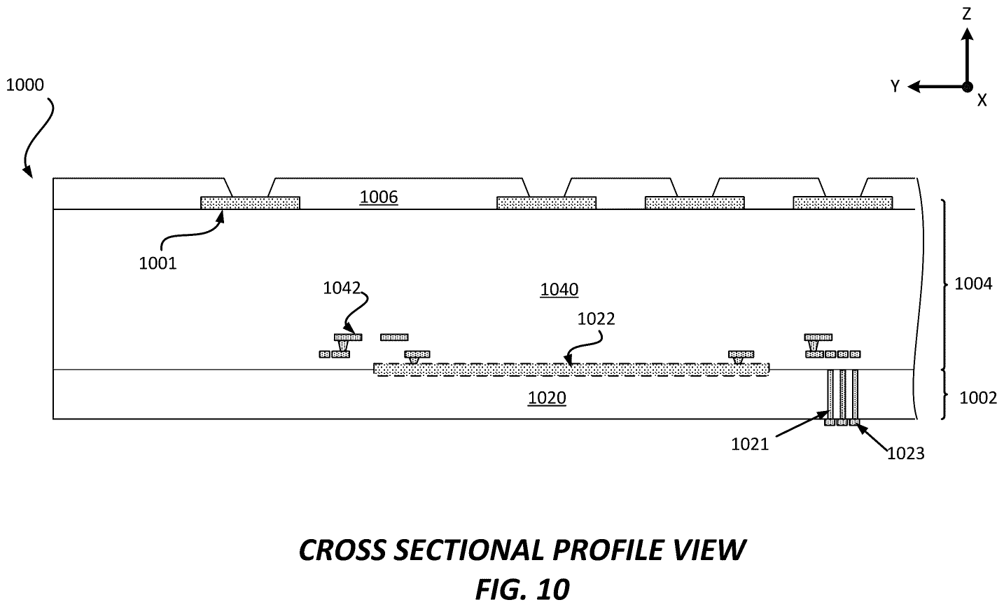

FIG. 8 illustrates a plan view of the package 700 of FIG. 7. The package 700 includes the integrated device 103, the substrate 104, the memory device 107 and the heat sink 105. The integrated device 103 includes an active region 501. The active region 501 includes a plurality of transistors. The active region 501 is located in a top left portion of the integrated device 103. At least part of the substrate 104 may include a plurality of heat sink interconnects.

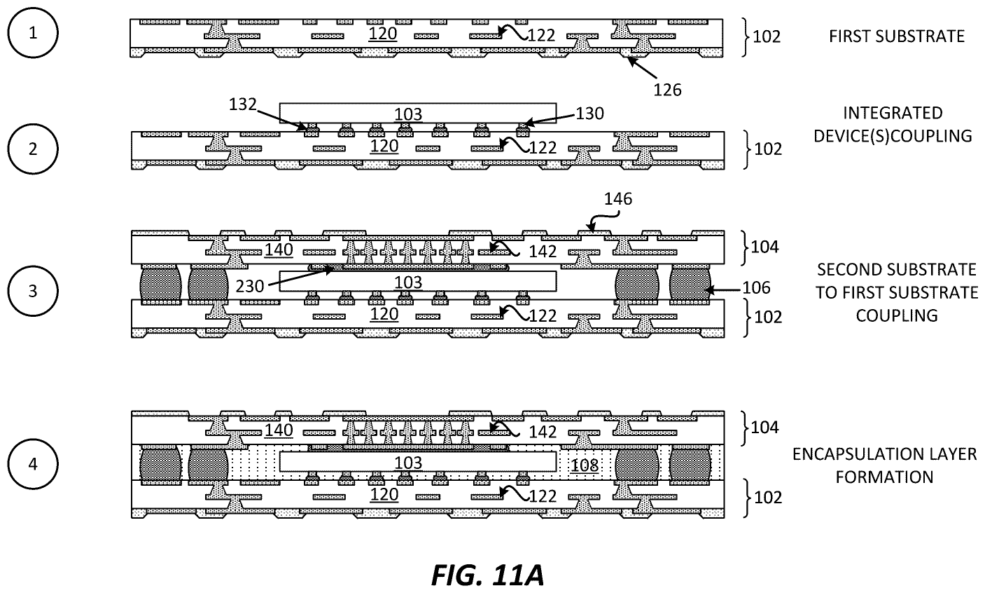

FIG. 9 illustrates an exemplary temperature map 900 of the package 700. The temperature map 900 may illustrate an example of a temperature distribution of the integrated device 103 with a heat sink that is offset to the integrated device 103. As shown in FIG. 9, the portion of the integrated device 103 that is above the active region 501 has the highest temperatures and the temperature of a specific portion of the integrated device 103 decreases the further away it is from the active region 501.

### Exemplary Integrated Device

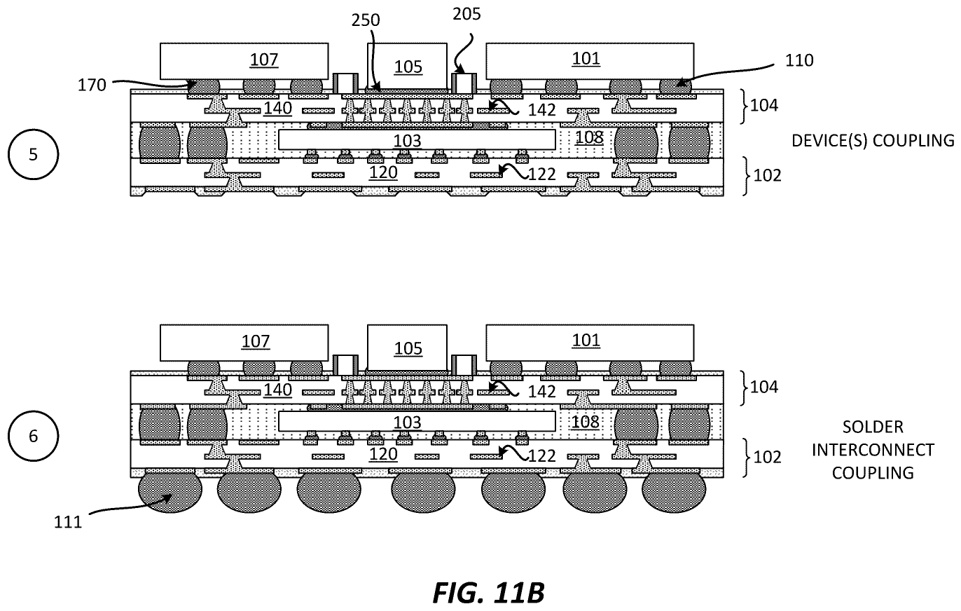

FIG. 10 illustrates a cross sectional profile view of an integrated device 1000 that includes a die substrate. The integrated device 1000 may represent the memory device 101, the integrated device 103 and/or the memory device 107. The integrated device 1000 can be a semiconductor die. The integrated device 1000 includes a die substrate portion 1002 and a die interconnection portion 1004. The die substrate portion 1002 includes a die substrate 1020, an active region 1022 and a plurality of through substrate vias 1021. The active region 1022 may include a plurality of logic cells, a plurality of transistors, and/or a plurality of filters. Different implementations may use different types of transistors, such as a field effect transistor (FET), planar FET, finFET, and a gate all around FET. In some implementations, a front end of line (FEOL) process may be used to fabricate the active region 1022 of the die substrate 1020.

The die substrate 1020 may include silicon (Si). The die substrate 1020 may comprise a bulk silicon. The bulk silicon may include a monolith silicon. The plurality of through substrate vias 1021 may extend through the die substrate 1020. Different implementations may have different thicknesses for the die substrate 1020.

The die interconnection portion 1004 includes at least one dielectric layer 1040 and a plurality of die interconnects 1042. The die interconnection portion 1004 is coupled to the die substrate portion 1002. The plurality of die interconnects 1042 is coupled to the active region 1022 of the die substrate portion 1002. The plurality of die interconnects 1042 may be coupled to the plurality of through substrate vias 1021. The die interconnection portion 1004 may also include a plurality of pad interconnects 1001 and a passivation layer 1006. In some implementations, a back end of line (BEOL) process may be used to fabricate the die interconnection portion 1004. A plurality of metallization interconnects 1023 may be coupled to the plurality of through substrate vias 1021. The plurality of metallization interconnects 1023 may be part of backside metallization portion that is coupled to the die substrate portion 1002. The integrated device 1000 may include a front side and a backside. The front side of the integrated device 1000 may be a side that includes the plurality of pad interconnects 1001. The back side of the integrated device 1000 may be a side that includes the die substrate portion 1002 and/or the die substrate 1020.

In some implementations, an electrical path to and/or from an active region 1022 may include at least one die interconnect from the plurality of die interconnects 1042, at least one through substrate via from the plurality of through substrate vias 1021. In some implementations, an electrical path to and/or from an active region 1022 may include at least one die interconnect from the plurality of die interconnects 1042, at least one pad interconnect from the plurality of pad interconnects 1001.

An integrated device (e.g., 103) may include a die (e.g., semiconductor bare die). Thus, an integrated device as used in the disclosure can mean a semiconductor die that includes transistors. In some implementations, an integrated device can mean a chip. A chip can include a semiconductor die and additional interconnects (e.g., packaging interconnects). A chip can include a flip chip. In some implementations, an integrated device can mean a system on chip (SoC). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc.). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one or more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package may be fabricated using the same technology node or different technology nodes. In some implementations, a chiplet and another chiplet of a package may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap width between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node.

To manage the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node.

Examples of compute applications may include high performance computing and/or high-performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets.

Thus, the combination of using different technology nodes (which may have different associated yield loss) for different integrated devices and/or chiplets can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100, 200, 300, 400) may be implemented in a radio frequency (RF) package. The RF package may be a radio frequency front end (RFFE) package. A package (e.g., 100) may be configured to provide Wireless Fidelity (WiFi) communication and/or cellular communication (e.g., 2G, 3G, 4G, 5G). The packages (e.g., 100, 300, 400) may be configured to support Global System for Mobile (GSM) Communications, Universal Mobile Telecommunications System (UMTS), and/or Long-Term Evolution (LTE). The packages (e.g., 100, 200, 300, 400) may be configured to transmit and receive signals having different frequencies and/or communication protocols.

Having described various packages, a sequence for fabricating a package will now be described below.

### Exemplary Sequence for Fabricating a Package Comprising Substrates, Integrated Devices and a Heat Sink

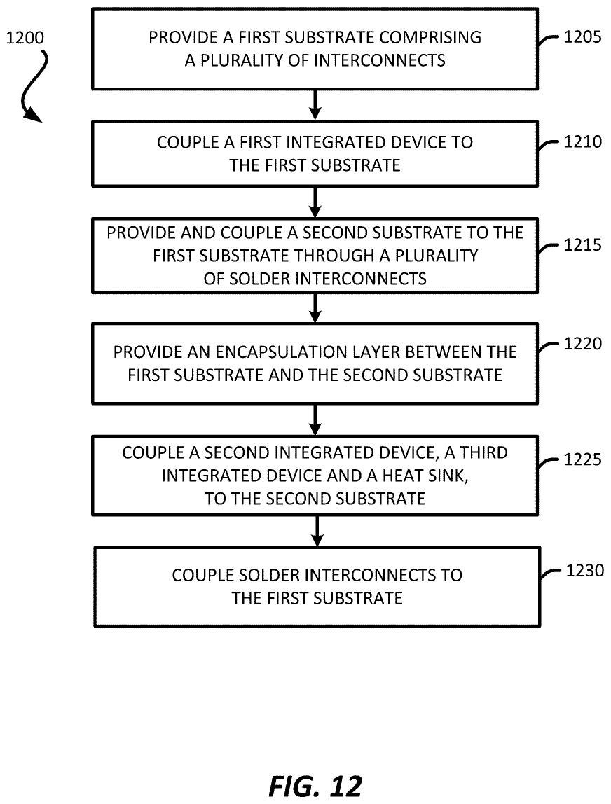

In some implementations, fabricating a package includes several processes. FIGS. 11A-11B illustrate an exemplary sequence for providing or fabricating a package. In some implementations, the sequence of FIGS. 11A-11B may be used to provide or fabricate the package 200. However, the process of FIGS. 11A-11B may be used to fabricate any of the packages (e.g., 100, 300, 400) described in the disclosure.

It should be noted that the sequence of FIGS. 11A-11B may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

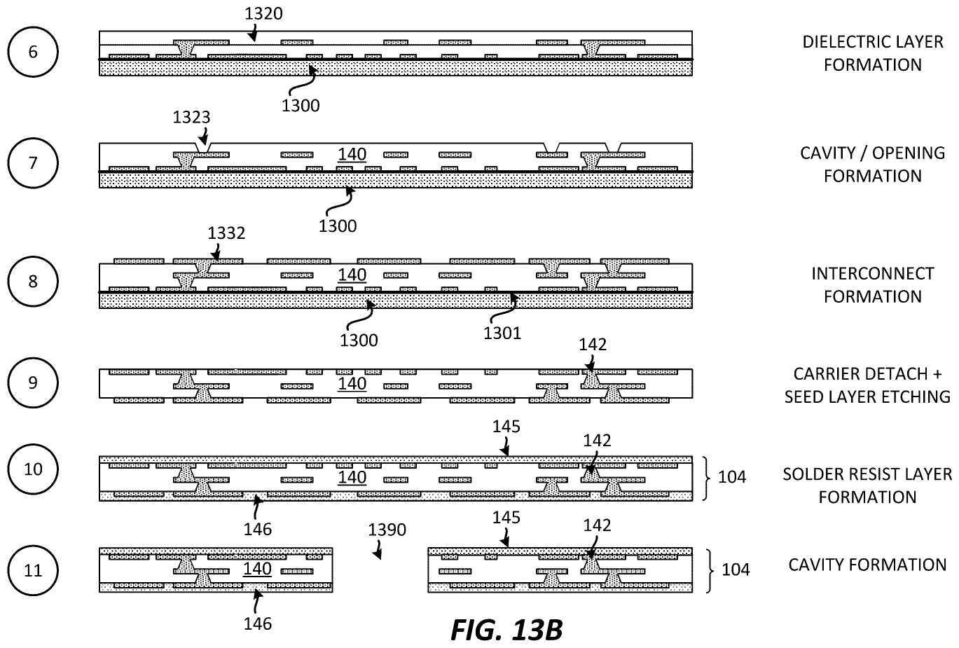

Stage 1, as shown in FIG. 11A, illustrates a state after a substrate 102 is provided. The substrate 102 may be a first substrate. The substrate 102 includes at least one dielectric layer 120, a plurality of interconnects 122 and a solder resist layer 126. The substrate 102 may include a first surface (e.g., top surface) and a second surface (e.g., bottom surface). The substrate 102 may be fabricated using the method as described in FIGS. 13A-13B.

Stage 2 illustrates a state after an integrated device 103 is coupled to the first surface (e.g., top surface) of the substrate 102. The integrated device 103 may be coupled to the substrate 102 through the plurality of pillar interconnects 130 and the plurality of solder interconnects 132. In some implementations, the integrated device 103 may be coupled to the substrate 102 through the plurality of solder interconnects 132. A solder reflow process may be used to couple the integrated device 103 to the substrate 102.

Stage 3 illustrates a state after a substrate 104 is provided and coupled to the substrate 102 through a plurality of solder interconnects 106. The substrate 104 may be a second substrate. The substrate 104 includes at least one dielectric layer 140, a plurality of interconnects 142 and a solder resist layer 146. The substrate 104 may include a first surface (e.g., top surface) and a second surface (e.g., bottom surface). The substrate 104 may be fabricated using the method as described in FIGS. 13A-13B. In some implementations, the substrate 104 may include a cavity as shown in FIG. 4.

A solder reflow process may be used to couple the substrate 104 to the substrate 102. The plurality of solder interconnects 106 may be coupled to the substrate 102 and the substrate 104. The plurality of solder interconnects 106 may be coupled to and touching the plurality of interconnects 122 and the plurality of interconnects 142. The substrate 104 is coupled to the substrate 102 such that the integrated device 103 is located between the substrate 102 and the substrate 104. In some implementations, a plurality of solder interconnects are provided and/or coupled to the substrate 102 and the substrate 104 separately before coupling the substrate 104 to the substrate 102. The substrate 104 may be coupled to the back side of the integrated device 103. An adhesive, a thermal interface material (TIM) (e.g., 230) and/or a solder interconnect may be used to couple interconnects of the substrate 104 to the back side of the integrated device 103.

Stage 4 illustrates a state after an encapsulation layer 108 is provided between the substrate 102 and the substrate 104. The encapsulation layer 108 may at least partially encapsulate the integrated device 103, the plurality of solder interconnects 106. The encapsulation layer 108 may be located between the substrate 102 and the substrate 104. The encapsulation layer 108 may be located between the back side of the integrated device 103 and the substrate 104. The encapsulation layer 108 may be located laterally to the plurality of solder interconnects 106. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

Stage 5, as shown in FIG. 11B, illustrates a state after a memory device 101, a memory device 107 and a heat sink 105 are coupled to the first surface (e.g., top surface) of the substrate 104. The memory device 101 may be a second integrated device. The memory device 107 may be coupled to the substrate 104 through the plurality of solder interconnects 110. The memory device 107 may be coupled to the substrate 104 through the plurality of solder interconnects 170. A solder reflow process may be used to couple the memory device 101 and/or the memory device 107 to the substrate 104. An adhesive, a thermal interface material (TIM) (e.g., 250) and/or solder interconnect may be used to couple the heat sink 105 to the substrate 104. Stage 5 also illustrates a passive device 205 coupled to the substrate 104. The passive device 205 may be coupled to the substrate 104 through a solder interconnect. A solder reflow process may be used to couple the passive device 205 to the substrate 104. In some implementations, the heat sink 105 may be coupled to the back side of the integrated device 103, through a cavity in the substrate 104, as shown and described in FIG. 4.

Stage 6 illustrates a state after a plurality of solder interconnects 111 are coupled to the second surface of the substrate 102. A solder reflow process may be used to couple the plurality of solder interconnects 111 to the substrate 102. Stage 6 may illustrate the package 200. The package 200 may be fabricated one at a time or may be fabricated together as part of one or more wafers and/or panels, and then singulated into individual packages.

### Exemplary Flow Diagram of a Method for Fabricating a Package Including Substrates, Integrated Devices and a Heat Sink

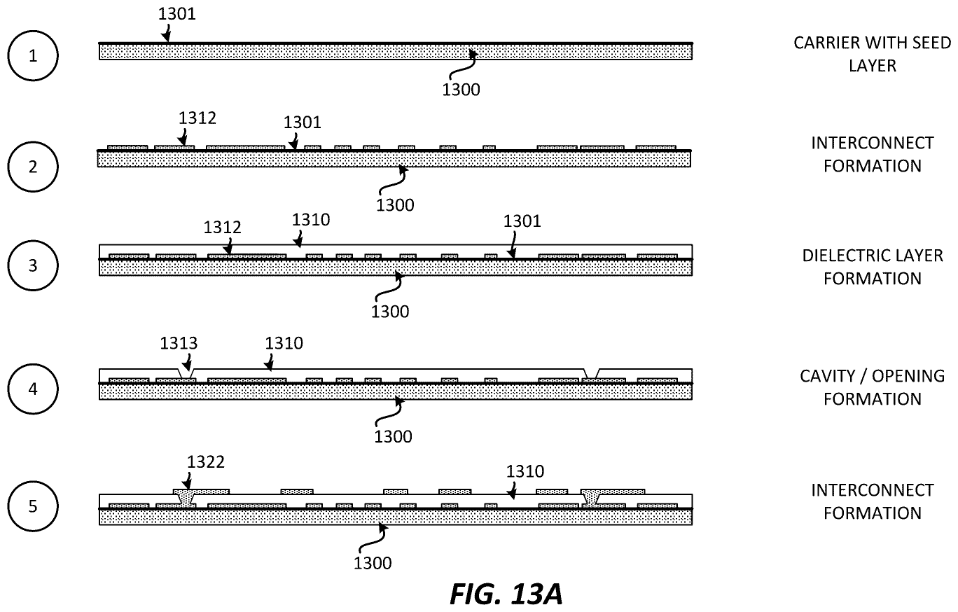

In some implementations, fabricating a package includes several processes. FIG. 12 illustrates an exemplary flow diagram of a method 1200 for providing or fabricating a package. In some implementations, the method 1200 of FIG. 12 may be used to provide or fabricate the package 200 described in the disclosure. However, the method 1200 may be used to provide or fabricate any of the packages (e.g., 100, 300, 400) described in the disclosure.

It should be noted that the method 1200 of FIG. 12 may combine one or more processes in order to simplify and/or clarify the method for providing or fabricating a package. In some implementations, the order of the processes may be changed or modified.

The method provides (at 1205) a first substrate that includes a plurality of interconnects. Stage 1 of FIG. 11A, illustrates and describes an example of a state after a substrate 102 is provided. The substrate 102 may be a first substrate. The substrate 102 includes at least one dielectric layer 120, a plurality of interconnects 122 and a solder resist layer 126. The substrate 102 may include a first surface (e.g., top surface) and a second surface (e.g., bottom surface). The substrate 102 may be fabricated using the method as described with reference to FIGS. 13A-13B.

The method couples (at 1210) a first integrated device to the first substrate. Stage 2 of FIG. 11A, illustrates and describes an example of a state after an integrated device 103 is coupled to the first surface (e.g., top surface) of the substrate 102. The integrated device 103 may be coupled to the substrate 102 through the plurality of pillar interconnects 130 and the plurality of solder interconnects 132. In some implementations, the integrated device 103 may be coupled to the substrate 102 through the plurality of solder interconnects 132. A solder reflow process may be used to couple the integrated device 103 to the substrate 102.

The method provides and couples (at 1215) a second substrate to the first substrate through a plurality of solder interconnects. Stage 3 of FIG. 11A, illustrates and describes an example of a state after a substrate 104 is provided and coupled to the substrate 102 through a plurality of solder interconnects 106. The substrate 104 may be a second substrate. The substrate 104 includes at least one dielectric layer 140, a plurality of interconnects 142 and a solder resist layer 146. The substrate 104 may include a first surface (e.g., top surface) and a second surface (e.g., bottom surface). The substrate 104 may be fabricated using the method as described in FIGS. 13A-13B. In some implementations, the substrate 104 may include a cavity as shown in FIG. 4.

A solder reflow process may be used to couple the substrate 104 to the substrate 102. The plurality of solder interconnects 106 may be coupled to the substrate 102 and the substrate 104. The plurality of solder interconnects 106 may be coupled to and touching the plurality of interconnects 122 and the plurality of interconnects 142. The substrate 104 is coupled to the substrate 102 such that the integrated device 103 is located between the substrate 102 and the substrate 104. In some implementations, a plurality of solder interconnects are provided and/or coupled to the substrate 102 and the substrate 104 separately before coupling the substrate 104 to the substrate 102. The substrate 104 may be coupled to the back side of the integrated device 103. An adhesive, a thermal interface material (TIM) (e.g., 230) and/or a solder interconnect may be used to couple interconnects of the substrate 104 to the back side of the integrated device 103.

The method provides (at 1220) an encapsulation layer between the first substrate and the second substrate. Stage 4 of FIG. 11A illustrates and describes an example of a state after an encapsulation layer 108 is provided between the substrate 102 and the substrate 104. The encapsulation layer 108 may at least partially encapsulate the integrated device 103, the plurality of solder interconnects 106. The encapsulation layer 108 may be located between the substrate 102 and the substrate 104. The encapsulation layer 108 may be located between the back side of the integrated device 103 and the substrate 104. The encapsulation layer 108 may be located laterally to the plurality of solder interconnects 106. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

The method couples (at 1225) integrated device(s) and/or heat sink(s) to the second substrate. Stage 5 of FIG. 11B, illustrates and describes an example of a state after a memory device 101, a memory device 107 and a heat sink 105 are coupled to the first surface (e.g., top surface) of the substrate 104. The memory device 101 may be a second integrated device. The memory device 107 may be coupled to the substrate 104 through the plurality of solder interconnects 110. The memory device 107 may be coupled to the substrate 104 through the plurality of solder interconnects 170. A solder reflow process may be used to couple the memory device 101 and/or the memory device 107 to the substrate 104. An adhesive, a thermal interface material (TIM) (e.g., 250) and/or solder interconnect may be used to couple the heat sink 105 to the substrate 104. Stage 5 also illustrates a passive device 205 coupled to the substrate 104. The passive device 205 may be coupled to the substrate 104 through a solder interconnect. A solder reflow process may be used to couple the passive device 205 to the substrate 104. In some implementations, the heat sink 105 may be coupled to the back side of the integrated device 103, through a cavity in the substrate 104, as shown and described in FIG. 4.

The method couples (at 1230) a plurality of solder interconnects to the first substrate. Stage 6 of FIG. 11B illustrates and describes an example of a state after a plurality of solder interconnects 111 are coupled to the second surface of the substrate 102. A solder reflow process may be used to couple the plurality of solder interconnects 111 to the substrate 102. Stage 6 may illustrate the package 200. The package 200 may be fabricated one at a time or may be fabricated together as part of one or more wafers and/or panels, and then singulated into individual packages.

### Exemplary Sequence for Fabricating a Substrate

In some implementations, fabricating a substrate includes several processes. FIGS. 13A-13B illustrate an exemplary sequence for providing or fabricating a substrate. In some implementations, the sequence of FIGS. 13A-13B may be used to provide or fabricate the substrate 104. However, the process of FIGS. 13A-13B may be used to fabricate any of the substrates (e.g., 102) described in the disclosure.

It should be noted that the sequence of FIGS. 13A-13B may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 13A, illustrates a state after a carrier 1300 is provided. A seed layer 1301 may be located over the carrier 1300.

Stage 2 illustrates a state after a plurality of interconnects 1312 are formed. The interconnects 1312 may be located over the seed layer 1301. A lithography process, a plating process, a strip process and/or an etching process may be used to form the plurality of interconnects 1312. The interconnects 1312 may represent at least some of the interconnects from the plurality of interconnects 142.

Stage 3 illustrates a state after a dielectric layer 1310 is formed over the carrier 1300, the seed layer 1301 and the plurality of interconnects 1312. A deposition and/or lamination process may be used to form the dielectric layer 1310. The dielectric layer 1310 may include prepreg and/or polyimide. The dielectric layer 1310 may include a photo-imageable dielectric. However, different implementations may use different materials for the dielectric layer.

Stage 4 illustrates a state after a plurality of cavities 1313 is formed in the dielectric layer 1310. The plurality of cavities 1313 may be formed using an etching process (e.g., photo etching process), a laser process, an exposure process and/or a development process.

Stage 5 illustrates a state after interconnects 1322 are formed in and over the dielectric layer 1310, including in and over the plurality of cavities 1313. For example, a via, pad and/or traces may be formed. A lithography process, a plating process, a strip process and/or an etching process may be used to form the interconnects.

Stage 6, as shown in FIG. 13B, illustrates a state after a dielectric layer 1320 is formed over the dielectric layer 1310 and the plurality of interconnects 1322. A deposition and/or lamination process may be used to form the dielectric layer 1320. The dielectric layer 1320 may include prepreg and/or polyimide. The dielectric layer 1320 may include a photo-imageable dielectric. However, different implementations may use different materials for the dielectric layer.

Stage 7 illustrates a state after a plurality of cavities 1323 is formed in the dielectric layer 140. The dielectric layer 140 may represent the dielectric layer 1310 and/or the dielectric layer 1320. The plurality of cavities 1323 may be formed using an etching process (e.g., photo etching process), a laser process, an exposure process and/or a development process.

Stage 8 illustrates a state after interconnects 1332 are formed in and over the dielectric layer 140, including in and over the plurality of cavities 1323. For example, a via, pad and/or traces may be formed. A lithography process, a plating process, a strip process and/or an etching process may be used to form the interconnects.

Stage 9 illustrates a state after the carrier 1300 is decoupled (e.g., detached, removed, grinded out) from at least one dielectric layer 140 and the seed layer 1301, portions of the seed layer 1301 are removed (e.g., etched out), leaving the substrate 104 that includes at least one dielectric layer 140 and the plurality of interconnects 142. The plurality of interconnects 142 may represent the plurality of interconnects 1312, the plurality of interconnects 1322 and/or the plurality of interconnects 1332.

Stage 10 illustrates a state after the solder resist layer 145 is formed over the first surface of the substrate 104, and after the solder resist layer 146 is formed over the second surface of the substrate 104. A deposition process and/or lamination process may be used to form the solder resist layer 145 and/or the solder resist layer 146. The solder resist layer 145 and/or the solder resist layer 146 may include openings. An etching process, an exposure process and/or a development process may be used to form the openings in the solder resist layer 145 and/or the openings in the solder resist layer 146.

Stage 11 illustrates a state after a cavity 1390 is formed through the substrate 104. The cavity 1390 may extend through the solder resist layer 145, the at least one dielectric layer 140 and the solder resist layer 146. A laser process (e.g., laser ablation) may be used to form the cavity 1390.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

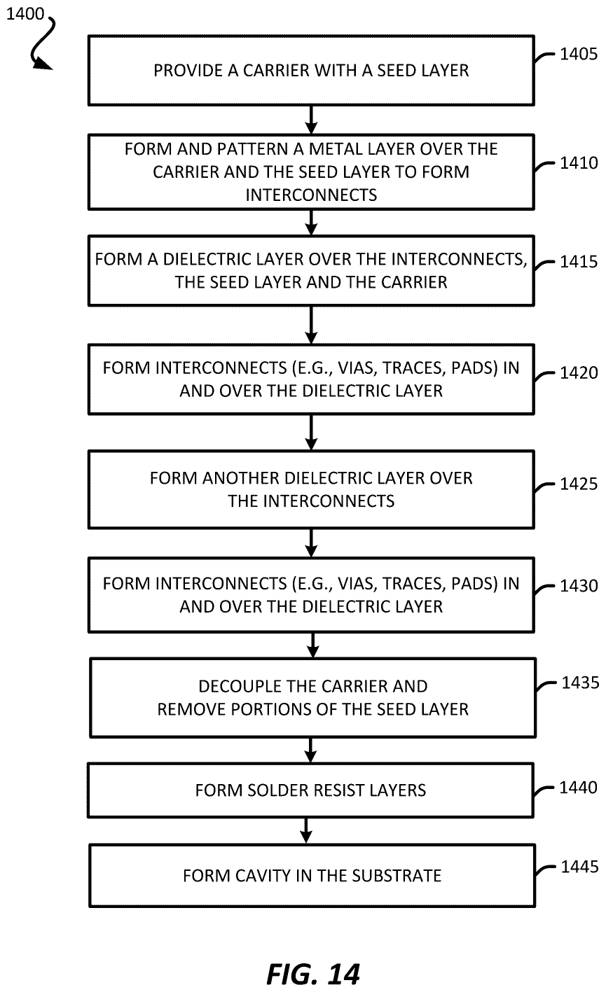

In some implementations, fabricating a substrate includes several processes. FIG. 14 is a process flow diagram illustrating processes of a method 1400 for providing or fabricating a substrate. In some implementations, the method 1400 of FIG. 14 may be used to provide or fabricate the substrate(s) of the disclosure. For example, the method 1400 of FIG. 14 may be used to fabricate the substrate 104.

It should be noted that the method 1400 of FIG. 14 may combine one or more processes in order to simplify and/or clarify the method for providing or fabricating a substrate. In some implementations, the order of the processes may be changed or modified.

The method provides (at 1405) a carrier with a seed layer. Stage 1 of FIG. 13A illustrates and describes an example of a state after a carrier 1300 is provided. A seed layer 1301 may be located over the carrier 1300.

The method forms and patterns (at 1410) a plurality of interconnects. Stage 2 of FIG. 13A, illustrates and describes an example of a state after a plurality of interconnects 1312 are formed. The interconnects 1312 may be located over the seed layer 1301. A lithography process, a plating process, a strip process and/or an etching process may be used to form the plurality of interconnects 1312. The interconnects 1312 may represent at least some of the interconnects from the plurality of interconnects 142.

The method forms (at 1415) a dielectric layer. Stage 3 of FIG. 13A, illustrates and describes an example of a state after a dielectric layer 1310 is formed over the carrier 1300, the seed layer 1301 and the plurality of interconnects 1312. A deposition and/or lamination process may be used to form the dielectric layer 1310. The dielectric layer 1310 may include prepreg and/or polyimide. The dielectric layer 1310 may include a photo-imageable dielectric. However, different implementations may use different materials for the dielectric layer.

The method forms (at 1420) a plurality of interconnects. Forming a plurality of interconnects may include forming a plurality of cavities in a dielectric layer and performing a plating process. Stage 4 of FIG. 13A, illustrates and describes an example of a state after a plurality of cavities 1313 is formed in the dielectric layer 1310. The plurality of cavities 1313 may be formed by using an etching process (e.g., photo etching process), a laser process, an exposure process and/or a development process.

Stage 5 of FIG. 13A illustrates and describes an example of a state after interconnects 1322 are formed in and over the dielectric layer 1310, including in and over the plurality of cavities 1313. For example, a via, pad and/or traces may be formed. A lithography process, a plating process, a strip process and/or an etching process may be used to form the interconnects.

The method forms (at 1425) another dielectric layer. Stage 6 of FIG. 13B illustrates and describes an example of a state after a dielectric layer 1320 is formed over the dielectric layer 1310 and the plurality of interconnects 1322. A deposition and/or lamination process may be used to form the dielectric layer 1320. The dielectric layer 1320 may include prepreg and/or polyimide. The dielectric layer 1320 may include a photo-imageable dielectric. However, different implementations may use different materials for the dielectric layer.

The method forms (at 1430) a plurality of interconnects. Forming a plurality of interconnects may include forming a plurality of cavities in a dielectric layer and performing a plating process. Stage 7 of FIG. 13B illustrates and describes an example of a state after a plurality of cavities 1323 is formed in the dielectric layer 140. The dielectric layer 140 may represent the dielectric layer 1310 and/or the dielectric layer 1320. The plurality of cavities 1323 may be formed using an etching process (e.g., photo etching process), a laser process, an exposure process and/or a development process.

Stage 8 of FIG. 13B illustrates and describes an example of a state after interconnects 1332 are formed in and over the dielectric layer 140, including in and over the plurality of cavities 1323. For example, a via, pad and/or traces may be formed. A lithography process, a plating process, a strip process and/or an etching process may be used to form the interconnects.

The method decouples (at 1435) a carrier. Stage 9 of FIG. 13B, illustrates and describes an example of a state after the carrier 1300 is decoupled (e.g., detached, removed, grinded out) from at least one dielectric layer 140 and the seed layer 1301, portions of the seed layer 1301 are removed (e.g., etched out), leaving the substrate 104 that includes at least one dielectric layer 140 and the plurality of interconnects 142. The plurality of interconnects 142 may represent the plurality of interconnects 1312, the plurality of interconnects 1322 and/or the plurality of interconnects 1332.

The method forms (at 1440) solder resist layers. Stage 10 of FIG. 13B illustrates and describes an example of a state after the solder resist layer 145 is formed over the first surface of the substrate 104, and after the solder resist layer 146 is formed over the second surface of the substrate 104. A deposition process and/or lamination process may be used to form the solder resist layer 145 and/or the solder resist layer 146. An etching process, an exposure process and/or a development process may be used to form the openings in the solder resist layer 145 and/or the openings in the solder resist layer 146.

The method forms (at 1445) a cavity in the substrate. Stage 11 of FIG. 13B illustrates and describes an example of a state after a cavity 1390 is formed through the substrate 104. The cavity 1390 may extend through the solder resist layer 145, the at least one dielectric layer 140 and the solder resist layer 146. A laser process (e.g., laser ablation) may be used to form the cavity 1390.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

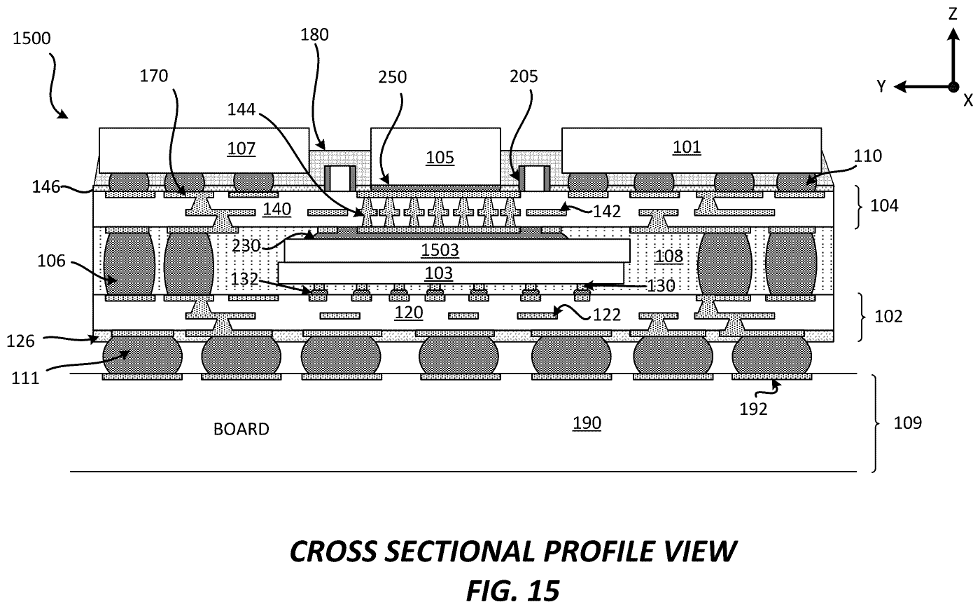

In some implementations, a stack of integrated devices may be located between two substrates. FIGS. 15-17 illustrate various examples of packages with substrates, a stack of integrated devices and a heat sink.

FIG. 15 illustrates a cross sectional profile view of a package 1500 that includes substrates, a stack of integrated devices and a heat sink. The package 1500 may be implemented as part of a package on package (PoP). The package 1500 is similar to the package 200 and may include similar components that are arranged in a similar manner as the package 200. As such, at least some of the description of the package 200 is applicable to the package 1500. The package 1500 includes a stack of integrated devices located between substrates. The package 1500 includes a substrate 102, a substrate 104, a memory device 101, an integrated device 103, an integrated device 1503, a memory device 107, a heat sink 105 and an encapsulation layer 108.

The integrated device 103 and the integrated device 1503 may form a stack of integrated devices. The integrated device 1503 may be coupled to the integrated device 103. The integrated device 1503 may be configured to be electrically coupled to the integrated device 103. In some implementations, a front side of the integrated device 1503 is coupled to a back side of the integrated device 103. The integrated device 103 and the integrated device 1503 are located between the substrate 102 and the substrate 104. The thermal interface material (TIM) 230 may be coupled to the back side of the integrated device 1503. The substrate 104 is coupled to the back side of the integrated device 1503 through the thermal interface material (TIM) 230. In some implementations, the plurality of interconnects 144 may touch the integrated device 1503. The heat sink 105 may at least partially vertically overlap with the integrated device 1503. The heat sink 105 may at least partially vertically overlap with the plurality of interconnects 144. The plurality of interconnects 144 may at least partially overlap with the integrated device 1503. In some implementations, at least some of the heat generated by the integrated device 1503 may dissipate through the back side of the integrated device 1503, through the thermal interface material (TIM) 230, through the plurality of interconnects 144 and through the heat sink 105. In some implementations, an adhesive and/or a solder interconnect may be used to couple the substrate 104 to the integrated device 1503. In some implementations, there may not be the thermal interface material (TIM) 230. The encapsulation layer 108 may at least partially encapsulate the integrated device 103, the integrated device 1503 and/or the plurality of solder interconnects 106.

Different implementations may use the memory device 101 and/or the memory device 107 differently. In some implementations, the memory device 101 and/or the memory device 107 may be used, dedicated and/or accessible by any of the integrated devices (e.g., 103,1503). In some implementations, some or all of the memory capacity of the memory device 101 may be used by and/or dedicated to only one or more of the integrated devices (e.g., 103,1503). In some implementations, some or all of the memory capacity of the memory device 107 may be used by and/or dedicated to only one or more of the integrated devices (e.g., 103, 1503). In one example, the memory device 101 may be dedicated to the NPU functionality of an integrated device and/or the GPU functionality of an integrated device, and the memory device 107 may be dedicated to the CPU functionality and other functionality of an integrated device. In another example, the memory device 101 may be dedicated to the NPU functionality of an integrated device, and the memory device 107 may be dedicated to the CPU functionality of an integrated device, the GPU functionality of an integrated device and other functionality of an integrated device. In another example, the memory device 101 may be dedicated to be used by the integrated device 103, and the memory device 107 may be dedicated to be used by the integrated device 1503. In another example, the memory device 101 may be dedicated to be used by the integrated device 103 and the integrated device 1503, and the memory device 107 may be dedicated to be used only by the integrated device 1503. In another example, the memory device 101 may be dedicated to be used only by the integrated device 1503, and the memory device 107 may be dedicated to be used by the integrated device 103 and the integrated device 1503.

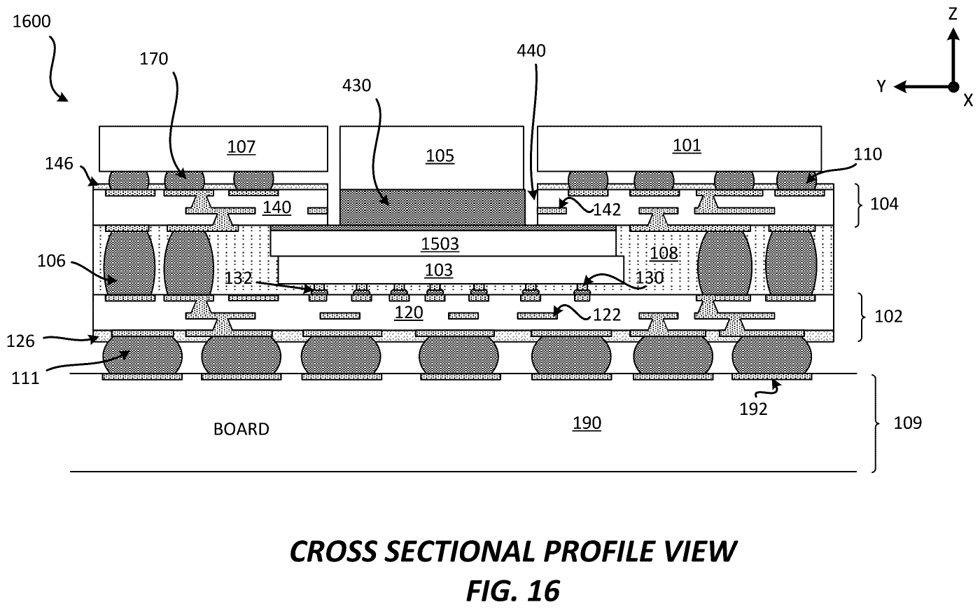

FIG. 16 illustrates a cross sectional profile view of a package 1600 that includes substrates, a stack of integrated devices and a heat sink. The package 1600 may be implemented as part of a package on package (PoP). The package 1600 is similar to the package 400 and may include similar components that are arranged in a similar manner to the package 400. As such, at least some of the description of the package 400 is applicable to the package 1600. The package 1600 includes a stack of integrated devices located between substrates. The package 1600 includes a substrate 102, a substrate 104, a memory device 101, an integrated device 103, an integrated device 1503, a memory device 107, a heat sink 105 and an encapsulation layer 108.

The integrated device 103 and the integrated device 1503 may form a stack of integrated devices. The integrated device 1503 may be coupled to the integrated device 103. The integrated device 1503 may be configured to be electrically coupled to the integrated device 103. In some implementations, a front side of the integrated device 1503 is coupled to a back side of the integrated device 103. The integrated device 103 and the integrated device 1503 are located between the substrate 102 and the substrate 104. The thermal interface material (TIM) 430 may be coupled to the back side of the integrated device 1503. The heat sink 105 is coupled to the back side of the integrated device 1503 through the thermal interface material (TIM) 430. The heat sink 105 may at least partially vertically overlap with the integrated device 1503. In some implementations, at least some of the heat generated by the integrated device 1503 may dissipate through the back side of the integrated device 1503, through the thermal interface material (TIM) 430 and through the heat sink 105. In some implementations, an adhesive and/or a solder interconnect may be used to couple the heat sink 105 to the integrated device 1503. The encapsulation layer 108 may at least partially encapsulate the integrated device 103, the integrated device 1503 and/or the plurality of solder interconnects 106.

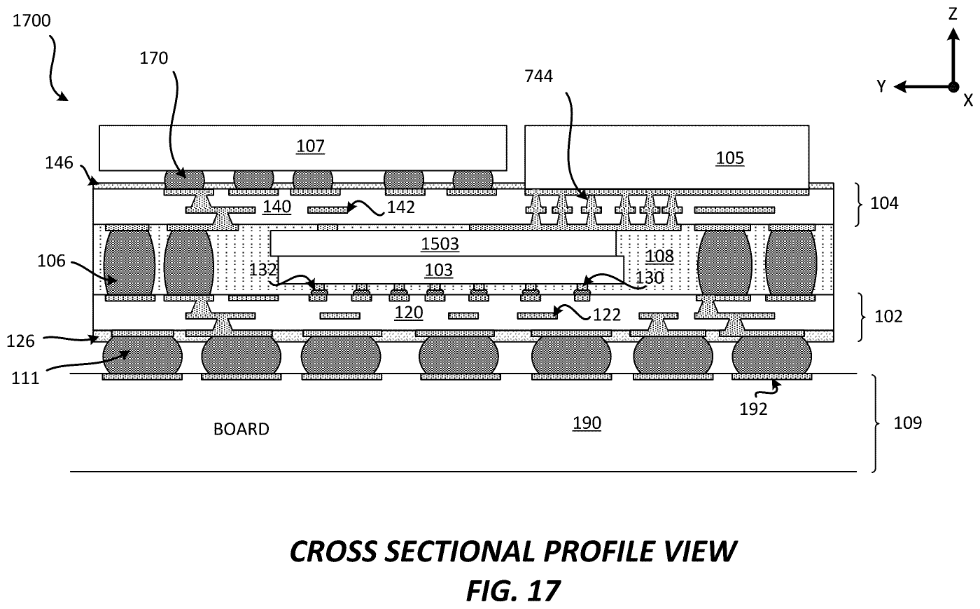

FIG. 17 illustrates a cross sectional profile view of a package 1700 that includes substrates, a stack of integrated devices and a heat sink. The package 1700 may be implemented as part of a package on package (PoP). The package 1700 is similar to the package 700 and may include similar components that are arranged in a similar manner to the package 700. As such, at least some of the description of the package 700 is applicable to the package 1700. The package 1700 includes a stack of integrated devices located between substrates. The package 1700 includes a substrate 102, a substrate 104, an integrated device 103, an integrated device 1503, a memory device 107, a heat sink 105 and an encapsulation layer 108.

The integrated device 103 and the integrated device 1503 may form a stack of integrated devices. The integrated device 1503 may be coupled to the integrated device 103. The integrated device 1503 may be configured to be electrically coupled to the integrated device 103. In some implementations, a front side of the integrated device 1503 is coupled to a back side of the integrated device 103. The integrated device 103 and the integrated device 1503 are located between the substrate 102 and the substrate 104.

The substrate 104 may be coupled to the integrated device 1503. The substrate 104 may touch the back side of the integrated device 1503. The plurality of heat sink interconnects 744 may touch the back side of the integrated device 1503. In some implementations, the substrate 104 and/or the plurality of heat sink interconnects 744 may be coupled to the integrated device 1503 through a thermal interface material (TIM), an adhesive and/or a solder interconnect.

It is noted that the use of a stack of integrated devices may be implemented in any of the packages described in the disclosure. In some implementations, a stack of integrated devices may include more than two integrated devices. In some implementations, two or more separate stacks of integrated devices may be located between two substrates.

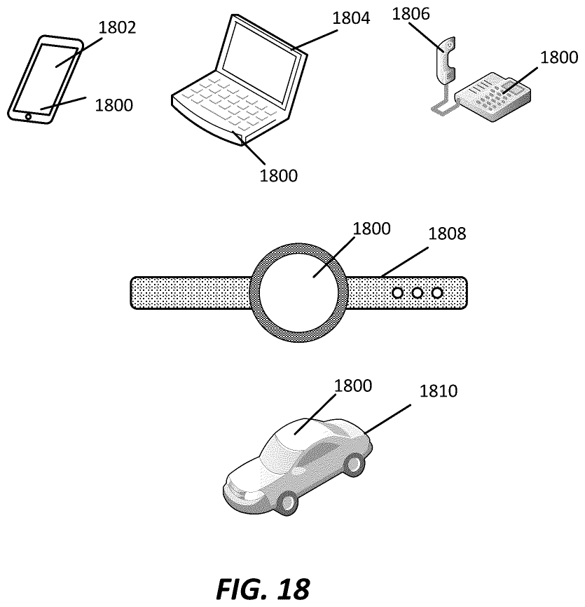

FIG. 18 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1802, a laptop computer device 1804, a fixed location terminal device 1806, a wearable device 1808, or automotive vehicle 1810 may include a device 1800 as described herein. The device 1800 may be, for example, any of the devices and/or integrated circuit (IC) packages described herein. The devices 1802, 1804, 1806 and 1808 and the vehicle 1810 illustrated in FIG. 18 are merely exemplary. Other electronic devices may also feature the device 1800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-10, 11A-11B, 12, 13A-13B, and 14-18 may be rearranged and/or combined into a single component, process, feature or function or embodied in several components, processes, or functions. Additional elements, components, processes, and/or functions may also be added without departing from the disclosure. It should also be noted FIGS. 1-10, 11A-11B, 12, 13A-13B, and 14-18 and its corresponding description in the present disclosure is not limited to dies and/or ICs. In some implementations, FIGS. 1-10, 11A-11B, 12, 13A-13B, and 14-18 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a panel, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, which is coupled to an object B, may be coupled to at least part of object B.

The term “electrically coupled” may mean that two objects are directly or indirectly coupled together such that an electrical current (e.g., signal, power, ground) may travel between the two objects. Two objects that are electrically coupled may or may not have an electrical current traveling between the two objects.

The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component.

The terms “encapsulate”, “encapsulating” and/or any derivation means that the object may partially encapsulate or completely encapsulate another object.

The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component.

A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a first substrate; an integrated device coupled to the first substrate; a second substrate; a heat sink coupled to the second substrate; a first memory device coupled to the second substrate; and a second memory device coupled to the second substrate, wherein the second memory device includes a different type of memory from the first memory device.

Aspect 2: The package of aspect 1, wherein a different type of memory includes a different memory capacity, a different memory density, a different memory architecture configuration and/or a different chiplet technology.

Aspect 3: The package of aspects 1 through 2, wherein the first memory device and the second memory device include Low Power Double Data Rate 5 (LPDDR5), Low Power Double Data Rate 6 (LPDDR6), LPDDR6X and/or Low Power Double Data Rate Accelerator in Memory (LPDDR-AIM).

Aspect 4: The package of aspects 1 through 3, wherein the integrated device includes a non-uniform memory access (NUMA) mechanism configured to manage data interleaving, memory write requests, and/or memory access requests across the first memory device and the second memory device,

Aspect 5: The package of aspect 4, wherein the NUMA mechanism is configured to accommodate differences between different memory types comprising one or more of memory access latency, memory capacity, processing-in-memory capabilities, and/or heat generation.

Aspect 6: The package of aspects 1 through 5, wherein the first memory device and/or the second memory device includes a processor configured to provide processing-in-memory (PIM) capability.

Aspect 7: The package of aspects 1 through 6, wherein the integrated device is a system on chip (SoC).

Aspect 8: The package of aspect 7, wherein the SoC includes one or more dies.

Aspect 9: The package of aspect 8, wherein the SoC includes a central processing unit (CPU) die, a graphics processing unit die (GPU) and/or a neural processing unit (NPU) die.

Aspect 10: The package of aspect 9, wherein the first memory device is dedicated to be used by the CPU die, and wherein the second memory device is dedicated to be used by the GPU die.

Aspect 11: The package of aspect 9, wherein the first memory device is dedicated to be used by the CPU die, and wherein the second memory device is dedicated to be used by the GPU die and the NPU die.

Aspect 12: The package of aspects 1 through 11, wherein the first memory device includes a first bus with a first number of bits, and wherein the second memory device includes a second bus with a second number of bits that is different from the first number of bits of the first bus.

Aspect 13: The package of aspects 1 through 12, wherein the first memory device includes a 16 bit bus, and wherein the second memory device includes a 24 bit bus.

Aspect 14: The package of aspects 1 through 13, further comprising an encapsulation layer located between the first substrate and the second substrate, wherein the first substrate is a first laminated substrate, and wherein the second substrate is a second laminated substrate.

Aspect 15: The package of aspect 14, wherein the second substrate is coupled to the first substrate through a plurality of solder interconnects.

Aspect 16: The package of aspects 1 through 15, wherein the heat sink is located laterally between the first memory device and the second memory device.

Aspect 17: The package of aspects 1 through 16, wherein the first memory device and/or the second memory device includes processing in memory (PIM) capability.

Aspect 18: The package of aspects 1 through 17, wherein the first memory device includes a first plurality of memory dies.

Aspect 19: The package of aspect 18, wherein the second memory device includes a second plurality of memory dies.

Aspect 20: The package of aspects 1 through 19, wherein the package includes a package on package (PoP),

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a first substrate:
an integrated device coupled to the first substrate;
a second substrate:
a heat sink coupled to the second substrate;
a first memory device coupled to the second substrate; and
a second memory device coupled to the second substrate, wherein the second memory device includes a different type of memory from the first memory device.

2. The package of claim 1, wherein a different type of memory includes a different memory capacity, a different memory density, a different memory architecture configuration and/or a different chiplet technology.

3. The package of claim 1, wherein the first memory device and the second memory device include Low Power Double Data Rate 5 (LPDDR5), Low Power Double Data Rate 6 (LPDDR6), LPDDR6X and/or Low Power Double Data Rate Accelerator in Memory (LPDDR-AIM).

4. The package of claim 1, wherein the integrated device includes a non-uniform memory access (NUMA) mechanism configured to manage data, interleaving, memory write requests, and/or memory access requests across the first memory device and the second memory device.

5. The package of claim 4, wherein the NUMA mechanism is configured to accommodate differences between different memory types comprising one or more of memory access latency, memory capacity, processing-in-memory capabilities, and/or heat generation.

6. The package of claim 1, wherein the first memory device and/or the second memory device includes a processor configured to provide processing-in-memory (PIM) capability.

7. The package of claim 1, wherein the integrated device is a system on chip (SoC).

8. The package of claim 7, wherein the SoC includes one or more dies.

9. The package of claim 8, wherein the SoC includes a central processing unit (CPU) die, a graphics processing unit die (GPU) and/or a neural processing unit (NPU) die.

10. The package of claim 9,
wherein the first memory device is dedicated to be used by the CPU die, and
wherein the second memory device is dedicated to be used by the GPU die.

11. The package of claim 9,
wherein the first memory device is dedicated to be used by the CPU die, and
wherein the second memory device is dedicated to be used by the GPU die and the NPU die.

12. The package of claim 1,
wherein the first memory device includes a first bus with a first number of bits, and
wherein the second memory device includes a second bus with a second number of bits that is different from the first number of bits of the first bus.

13. The package of claim 1,
wherein the first memory device includes a 16 bit bus, and
wherein the second memory device includes a 24 bit bus.

14. The package of claim 1, further comprising an encapsulation layer located between the first substrate and the second substrate,
wherein the first substrate is a first laminated substrate, and
wherein the second substrate is a second laminated substrate.

15. The package of claim 14, wherein the second substrate is coupled to the first substrate through a plurality of solder interconnects.

16. The package of claim 1, wherein the heat sink is located laterally between the first memory device and the second memory device.

17. The package of claim 1, wherein the first memory device and/or the second memory device includes processing in memory (PIM) capability.

18. The package of claim 1, wherein the first memory device includes a first plurality of memory dies.

19. The package of claim 18, wherein the second memory device includes a second plurality of memory dies.

20. The package of claim 1, wherein the package includes a package on package (PoP).
